(19) United States
(12) Patent Application Publication
(10) Pub. No.: US 2026/0206379 A1
(43) Pub. Date: Jul. 16, 2026

(54) DISPLAY DEVICE, MANUFACTURING METHOD OF THE SAME AND ELECTRONIC DEVICE

(71) Applicant: Samsung Display Co., Ltd., Yongin-si (KR)

(72) Inventors: Ki Chang EOM, Yongin-si (KR); Hyo Jin KO, Yongin-si (KR); Hui Won YANG, Yongin-si (KR)

(21) Appl. No.: 19/415,001

(22) Filed: Dec. 10, 2025

(30) Foreign Application Priority Data
Jan. 15, 2025 (KR) 10-2025-0005767

(51) Int. Cl. H10H 20/856; H10H 20/01; H10H 20/841; H10H 29/01; H10H 29/41

(52) U.S. Cl. CPC H10H 20/856; H10H 20/034; H10H 20/0363; H10H 20/841; H10H 29/012; H10H 29/41

(57) ABSTRACT

A display device includes an organic partition wall portion between first and second light-emitting elements, and comprising a first inclined portion toward the first light-emitting element and a second inclined portion toward the second light-emitting element, wherein the organic partition wall portion has a first angle between a first virtual surface, which extends parallel to the first light-emitting element, and an outer surface of the first inclined portion, and a second angle between a second virtual surface, which extends parallel to the second light-emitting element, and an outer surface of the second inclined portion, wherein the first angle is about 120 degrees or more, and the second angle is about 5 degrees or more larger than the first angle and about 135 degrees or less.

### CROSS-REFERENCE TO RELATED APPLICATION

This application claims priority to, and the benefit of, Korean Patent Application No. 10-2025-0005767, filed on January 15, 2025, in the Korean Intellectual Property Office, the entire disclosure of which is incorporated herein by reference.

### BACKGROUND

### Field

The present disclosure relates to a display device, a manufacturing method thereof, and an electronic device.

### Description of the Related Art

As the information society develops, the demand for display devices for displaying images is increasing in various forms. The display device may be a flat panel display device, such as a liquid crystal display, a field emission display, a light-emitting display, and the like.

The light-emitting display device may include an organic light-emitting display device including an organic light-emitting diode element as a light-emitting element, or an ultra-small light-emitting display device including a micro light-emitting diode element (hereinafter referred to as a micro light-emitting element) as a light-emitting element. Because the micro light-emitting diode element is made of an inorganic material, it has the aspect of having a long lifespan due to fewer deterioration issues compared to an organic light-emitting diode element.

The problem to be solved by the present disclosure is to provide a display device, a manufacturing method thereof, and an electronic device capable of increasing light emission efficiency.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, a display device includes a substrate, a thin film transistor layer above the substrate, a planarization layer above the thin film transistor layer, a pixel electrode layer above the planarization layer, light-emitting elements including a first light-emitting element and a second light-emitting element arranged along a first direction above the pixel electrode layer, an organic partition wall portion between the first light-emitting element and the second light-emitting element above the planarization layer, and including a first inclined portion toward the first light-emitting element and a second inclined portion toward the second light-emitting element, and wherein the first light-emitting element includes a first semiconductor layer, a first active layer configured to emit light of a first wavelength, and a second semiconductor layer, wherein the second light-emitting element includes a first semiconductor layer, a second active layer configured to emit light of a second wavelength that is different from the first wavelength, and a second semiconductor layer, wherein the organic partition wall portion has a first angle between a first virtual surface, which extends parallel to a boundary between the second semiconductor layer and the first active layer of the first light-emitting element, and an outer surface of the first inclined portion, and a second angle between a second virtual surface, which extends parallel to a boundary between the second semiconductor layer and the second active layer of the second light-emitting element, and an outer surface of the second inclined portion, wherein the first angle is about 120 degrees or more, and the second angle is about 5 degrees or more larger than the first angle and about 135 degrees or less.

The organic partition wall portion may include a 1-2 inclined portion above the first inclined portion, wherein the second semiconductor layer of the first light-

emitting element includes a lower surface facing the first active layer and an upper surface facing the lower surface, wherein the organic partition wall portion has a 1-2 angle between a 1-2 virtual surface, which extends parallel to the upper surface, and the outer surface of the 1-2 inclined portion, and wherein the 1-2 angle is smaller than the first angle, and an average of the 1-2 angle and the first angle is about 120 degrees or more.

The average of the 1-2 angle and the first angle may be about 120 degrees to about 135 degrees.

The organic partition wall portion may include an organic layer including the first inclined portion and the second inclined portion, and a reflective film above the organic layer, including a first reflective film on the outer surface of the first inclined portion, and a second reflective film on the outer surface of the second inclined portion, and having a third angle between the outer surface of the first reflective film and the first virtual surface, and a fourth angle between the outer surface of the second reflective film and the second virtual surface, wherein the third angle is about 120 degrees or more, and the fourth angle is about 5 degrees or more larger than the third angle and about 135 degrees or less.

The display device may further include a first protective film between the organic layer and the reflective film, and a second protective film outside the reflective film.

An inflection point of the first reflective film and the second reflective film may be higher than an upper portion of the first active layer, wherein the organic partition wall portion includes a 2-2 inclined portion and has a 2-2 angle between a 2-2 virtual surface, which extends parallel to the upper surface, and an outer surface of the 2-2 inclined portion, and wherein the 2-2 angle is smaller than the second angle, and an average of the 2-2 angle and the 2-2 angle is about 120 degrees or more.

A lower end portion of the reflective film may be lower than a lower end portion of the light-emitting elements, wherein a shortest distance between the reflective film and a corresponding one of the light-emitting elements is less than a width of the corresponding one of the light-emitting elements.

The organic partition wall portion may surround a corresponding one of the light-emitting elements in plan view.

An upper end of the reflective film may be at a height of about 80% or more and about 120% or less of a height of the light-emitting elements.

The light-emitting elements may further include a protective film on a side surface of the first semiconductor layer, a corresponding one of the first activation layer or the second active layer, and the second semiconductor layer, and does not have a reflective film on the protective film.

The display device may further include a common electrode above an upper portion of the light-emitting elements, wherein the pixel electrode layer includes pixel electrodes, and wherein the light-emitting elements are respectively above corresponding ones of the pixel electrodes.

The pixel electrode layer may include pixel electrodes and the common electrode spaced apart from each other, wherein the light-emitting elements are respectively above a corresponding one of the pixel electrodes and the common electrode.

The light-emitting elements may include a first contact electrode respectively above the corresponding one of the pixel electrodes, and a second contact electrode above the common electrode.

According to one or more embodiments of the present disclosure, a method for manufacturing a display device includes forming pixel electrodes above a planarization layer of a circuit board, forming an organic partition wall portion between a first pixel electrode and a second pixel electrode in plan view and above the circuit board, and having a first incline portion and a second inclined portion, forming a reflective film above the organic partition wall portion, arranging a first light-emitting element above the first pixel electrode and including a first semiconductor layer, a first active layer configured to emit light of a first wavelength, and a second semiconductor layer, and arranging a second light-emitting element above the second pixel electrode and including a first semiconductor layer, a second active layer configured to emit light of a second wavelength that is different from the first wavelength, and a second semiconductor layer, wherein the organic partition wall portion has a first angle between a first virtual surface, which extends parallel to a boundary between the second semiconductor layer and the first active layer of the first light-emitting element, and an outer surface of the first inclined portion, and a second angle between a second virtual surface, which extends parallel to a boundary between the second semiconductor layer and the second active layer of the second light-emitting element, and an outer surface of the second inclined portion, and wherein the first angle is about 120 degrees or more, and the second angle is about 5 degrees or more larger than the first angle and about 135 degrees or less.

The forming the organic partition wall portion may include forming a first organic layer above the circuit board, and forming a second organic layer including a 1-2 inclined portion above the first organic layer, and having a 1-2 angle between a 1-2 virtual surface, which extends parallel to an upper surface of the second semiconductor layer, and an outer surface of the 1-2 inclined portion, and wherein the 1-2 angle is smaller than the first angle, and an average of the first angle and the 1-2 angle is about 120 degrees or more.

The forming the reflective film may include forming a first protective material layer covering the first organic layer and the second organic layer above an entire surface of the circuit board, forming the reflective film above the first protective material layer overlapping the first organic layer and the second organic layer, forming a second protective material layer above the entire surface of the circuit board to cover the reflective film, and patterning a portion of the first protective material layer and the second protective material layer to form a first protective film and a second protective film exposing a corresponding one of the first pixel electrode or the second pixel electrode.

According to one or more embodiments of the present disclosure, an electronic device includes a display panel, a window above the display panel, and a bottom cover below the display panel, wherein the display panel includes, a substrate, a thin film transistor layer above the substrate, a planarization layer above the thin film transistor layer, a pixel electrode layer above the planarization layer, light-emitting elements including a first light-emitting element and a second light-emitting element arranged along a first direction above the pixel electrode layer, an organic partition wall portion between the first light-emitting element and the second light-emitting element in plan view and above the planarization layer, and including a first inclined portion toward the first light-emitting element and a second inclined portion toward the second light-emitting element, wherein the first light-emitting element includes a first semiconductor layer, a first active layer configured to emit light of a first wavelength, and a second semiconductor layer, wherein the second light-emitting element includes a first semiconductor layer, a second active layer configured to emit light of a second wavelength that is different from the first wavelength, and a second semiconductor layer, wherein the organic partition wall portion has a first angle between a first virtual surface, which extends parallel to a boundary between the second semiconductor layer and the first active layer of the first light-emitting element, and an outer surface of the first inclined portion, and a second angle between a second virtual surface, which extends parallel to a boundary between the second semiconductor layer and the second active layer of the second light-emitting element, and an outer surface of the second inclined portion, and wherein the first angle is about 120 degrees or more, and the second angle is about 5 degrees or more larger than the first angle and about 135 degrees or less.

The electronic device may further include a battery in a space at least partially defined by the bottom cover and configured to supply power to the display panel, and a middle frame between the window and the bottom cover.

The display panel may include a display area and a non-display area, wherein the display area includes a first display area and a second display area, wherein the first display area includes a 1-1 light-emitting element and a first organic partition wall portion surrounding the 1-1 light-emitting element in plan view, wherein the second display area includes a 2-1 light-emitting element and a second organic partition wall portion surrounding the 2-1 light-emitting element in plan view, and wherein a 11-1 angle between a 11-1 virtual surface, which is parallel to a boundary between a second semiconductor layer and a first active layer of the 1-1 light-emitting element, and the outer surface of the first inclined portion is smaller than a 11-2 angle between a 11-2 virtual surface, which is parallel to a boundary between a second semiconductor layer and a second active layer of the 2-1 light-emitting element, and the outer surface of the second inclined portion.

The second display area may be at an outer side of the first display area on a plane.

According to the display device and the manufacturing method thereof according to the embodiments, the light emission efficiency of the light-emitting element may be increased.

However, the aspects of the present disclosure are not limited to the aforementioned aspects, and various other aspects are included in the present specification.

### BRIEF DESCRIPTION OF THE DRAWINGS

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout drawing illustrating pixels of a display FIG. 5 is a layout drawing illustrating pixels of a display area according to one or more embodiments.

FIG. 6 is a cross-sectional view illustrating one example of a cross-section of a display panel taken along the line I-I’ in FIG. 5.

FIG. 7 is a cross-sectional view illustrating one example of area A of FIG. 6 in detail.

FIG. 8 is a cross-sectional view illustrating another example of area A of FIG. 6 in detail.

FIG. 9 is an enlarged view of a portion of FIG. 8.

FIG. 10 is a cross-sectional view illustrating another example of area A of FIG. 6 in detail according to one or more other embodiments.

FIG. 11 is a cross-sectional view illustrating another example of area A of FIG. 6 in detail.

FIG. 12 is a cross-sectional view illustrating an example of a cross-section of a display panel taken along the line I-I’ of FIG. 5 according to one or more other embodiments.

FIG. 13 is a layout diagram illustrating pixels of a display area according to one or more other embodiments.

FIG. 14a is a cross-sectional view illustrating an example of an organic partition taken along the line X1-X1’, the line X2-X2’, the line X3-X3’, and the line X4-X4’ of FIG. 13, and FIG. 14b is a cross-sectional view illustrating an example of an organic partition wall taken along the line Y1-Y1’ of FIG. 13 according to one or more other embodiments.

FIG. 15 is a layout diagram illustrating pixels of a display area according to one or more embodiments.

FIG. 16 is a cross-sectional diagram illustrating an example of a cross-section of a display panel taken along the line I2-I2’ of FIG. 15.

FIG. 17 is a cross-sectional diagram illustrating an example of B area of FIG. 16 in detail.

FIG. 18 is a cross-sectional diagram illustrating another example of B area of FIG. 16 in detail.

FIG. 19 is a cross-sectional diagram illustrating another example of B area of FIG. 16 in detail.

FIG. 20 is a graph illustrating LEE (light extraction efficiency) and luminance according to an angle of an organic partition wall.

FIG. 21 is a graph illustrating an emission profile according to an angle of an organic partition wall.

FIG. 22 is a flowchart illustrating a method of manufacturing a display device according to one or more embodiments.

FIG. 23 to FIG. 28 illustrate a method of manufacturing a display device according to one or more embodiments.

FIG. 29 is a plan view of a display panel according to one or more other embodiments.

FIG. 30 is a graph illustrating the simulation results of light emission of a light-emitting element depending on the presence or absence of an organic partition wall.

FIGS. 31 and 32 are drawings to illustrate a standard for measuring an angle of the outer surface of an organic partition wall according to one or more embodiments.

FIGS. 33 and 34 illustrate a smart watch including a display device according to one or more embodiments.

FIG. 35 is an exploded perspective view of a smart watch including a display device according to one or more embodiments.

FIGS. 36 and 37 are example views of a virtual reality (VR) device including a display device according to one or more embodiments.

FIG. 38 is a view of a VR device including a display device according to one or more embodiments.

FIG. 39 is a view illustrating a vehicle instrument cluster and center fascia including display devices according to one or more embodiments.

FIG. 40 is a view of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

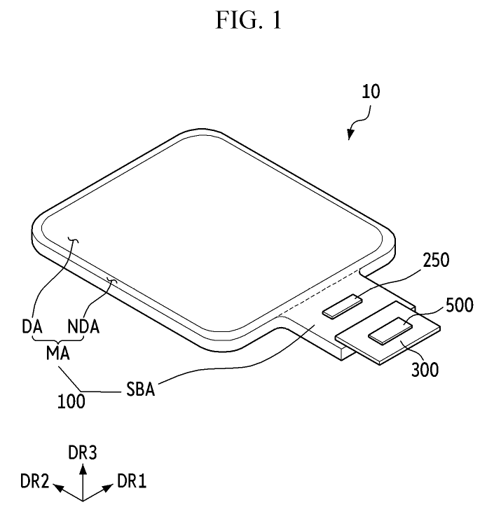

FIG. 1 is a perspective view illustrating a display device according to one or more embodiments.

Referring to FIG. 1, a display device 10 is a device for displaying video or still images, such as mobile phones, smart phones, tablet personal computers , and portable electronic devices, such as smart watches, watch phones, mobile communication terminals, electronic notebooks, e-books, portable electronic devices, such as portable multimedia players (PMP), navigation, and ultra mobile PC (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the present disclosure is not limited thereto. On the other hand, hereinafter, an ultra-small light-emitting diode is described as a light-emitting element for convenience of explanation.

The display device 10 includes a display panel 100, a display-driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a curvature (e.g., predetermined curvature) or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In addition, the display panel 100 may be flexibly formed to be bent, curved, bent, folded, or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits a first light, a second sub-pixel that emits a second light, and a third sub-pixel that emits a third light, but the embodiments of the present disclosure are not limited thereto.

The sub-area SBA may protrude from one side of the main area MA in the second direction DR2. Although FIG. 1 illustrates the sub-area SBA being unfolded, the sub-area SBA may be bent, and in this case, may be located on the lower surface of the display panel 100. When the sub-area SBA is bent, it may overlap the main area MA in a third direction DR3, which is the thickness direction of the display panel 100. The display-driving circuit 250 may be located in the sub-area SBA.

The display-driving circuit 250 may generate signals and voltages for driving the display panel 100. The display-driving circuit 250 may be formed as an integrated circuit (IC) and attached to the display panel 100 using a chip-on-glass (COG) method, a chip-on-plastic (COP) method, or an ultrasonic bonding method but is not limited thereto. In one or more embodiments, the display-driving circuit 250 may be attached to the circuit substrate 300 using a chip-on-film (COF) method.

The circuit substrate 300 may be attached to one end of the sub-area SBA of the display panel 100. As such, the circuit substrate 300 may be electrically connected to the display panel 100 and the display-driving circuit 250. The display panel 100 and the display-driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel-driving voltages according to an external power supply voltage. The power supply circuit 500 may be formed as an integrated circuit (IC) and attached to the circuit substrate 300 using a COF method.

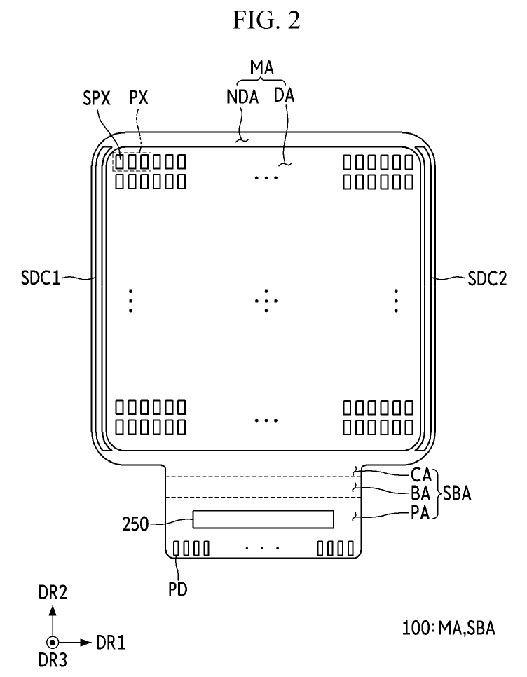

FIG. 2 is a layout drawing illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be located adjacent to the display area DA. The non-display area NDA may be an area outside the display area DA. The non-display area NDA may be arranged to surround the display area DA (e.g., in plan view). The non-display area NDA may be an edge area of the display panel 100.

A first scan-driving portion SDC1 and a second scan-driving portion SDC2 may be located in the non-display area NDA. The first scan-driving portion SDC1 is located on one side (e.g., the left side) of the display panel 100, and the second scan-driving portion SDC2 is located on the other side (e.g., the right side) of the display panel 100 but are not limited thereto. Each of the first scan-driving portion SDC1 and the second scan-driving portion SDC2 may be electrically connected to the display-driving circuit 250 through scan fan out lines. Each of the first scan-driving portion SDC1 and the second scan-driving portion SDC2 may receive a scan control signal from the display-driving circuit 250, generate scan signals according to the scan control signal, and output them to scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub area SBA may be less than the length of the first direction DR1 of the main area MA or may be substantially equal to the length of the first direction DR1 of the main area MA. The sub-area SBA may be curved and may be located at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display-driving circuit 250 are located. The display-driving circuit 250 may be attached to the driving pads of the pad area PA using a conductive adhesive member, such as an anisotropic conductive film. The circuit substrate 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

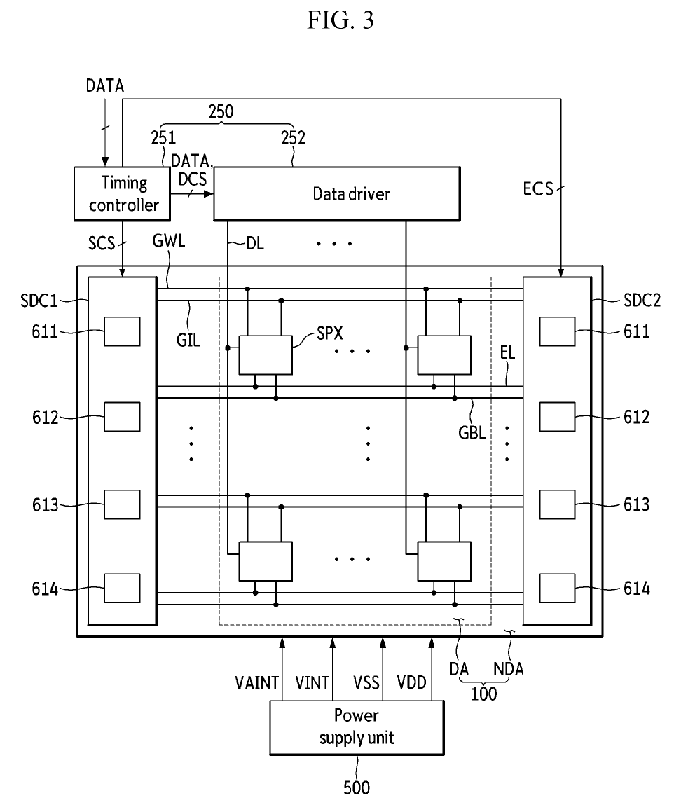

FIG. 3 is a block drawing illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and be located in the second direction DR2. The plurality of data lines DL may extend in the second direction DR2 and be located in the first direction DR1. The plurality of scan lines SL may include a a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light-emitting elements according to the data voltage.

The non-display area NDA includes a first scan-driving portion SDC1, a second scan driver SDC2, and a display-driving circuit 250.

Each of the first scan-driving portion SDC1 and the second scan-driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display-driving circuit 250 includes a timing control circuit 251 and a data-driving circuit 252.

The data-driving circuit 252 may receive digital video data DATA and a data timing control signal DCS from the timing control circuit 251. The data-driving circuit 252 converts digital video data DATA into analog data voltages according to the data timing control signal DCS and outputs them to the data lines DL. In this case, the sub-pixels SPX are selected by the write scan signals of the first scan driver SDC1 and the second scan driver SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan-driving portion SDC1 and the second scan-driving portion SDC2. The timing control circuit 251 may output digital video data DATA and a data timing control signal DCS to the data-driving circuit 252.

The power supply circuit 500 may generate a plurality of panel-driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

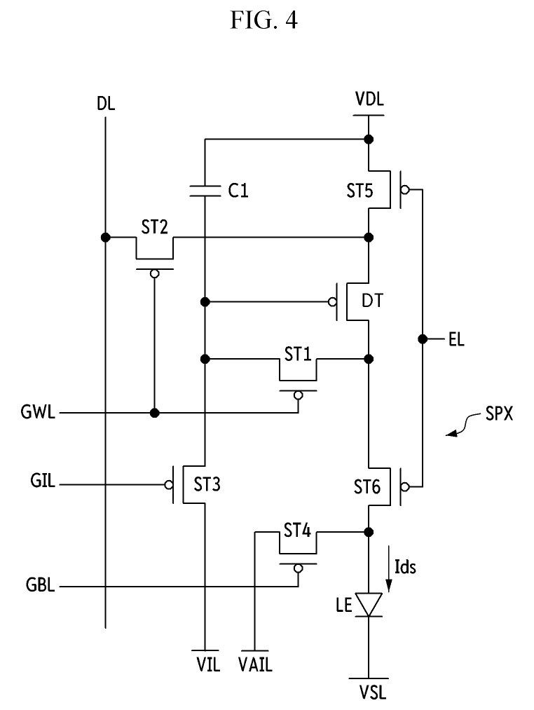

FIG. 4 is an equivalent circuit drawing illustrating a sub-pixel according to one or more embodiments.

Referring to FIG. 4, a sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to one or more embodiments includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as "driving current") flowing between the first electrode and the second electrode according to a data voltage applied to a gate electrode.

The light-emitting element LE1 may be a micro light-emitting diode. The light-emitting element LE emits light according to the driving current Ids. The amount of light emitted from the light-emitting element LE may be proportional to the driving current Ids. The anode electrode of the light-emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between a gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET and they may be turned on if a scan signal of a gate low voltage and an emission control signal are applied to the initialization scan line GIL, the write scan line GWL, the bias scan line GBL, and the emission line EL, respectively. One electrode of the third transistor ST3 may be connected to the first initialization voltage line VIL to which the third power supply voltage (VINT of FIG. 3) is applied, and one electrode of the fourth transistor ST4 may be connected to the second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, because the first transistor ST1 and the third transistor ST3 are formed as n-type MOSFET, the first transistor ST1 may be turned on if a scan signal of the gate high voltage is applied, and the third transistor ST3 may be turned on if an initialization scan signal of the gate high voltage is applied. In contrast, the second transistor ST2, the fourth transistor ST4, the fifth transistor ST5, and the sixth transistor ST6 are formed as p-type MOSFET, so they may be turned on if a scan signal of the gate low voltage and a light emission control signal are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on if a scan signal of a gate high voltage is applied, whereas the remaining transistors DT, ST1, ST2, ST3, ST5, and ST6 may be turned on if a scan signal of a gate low voltage and a light emission control signal are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on if a scan signal of a gate high voltage and a light emission control signal are applied.

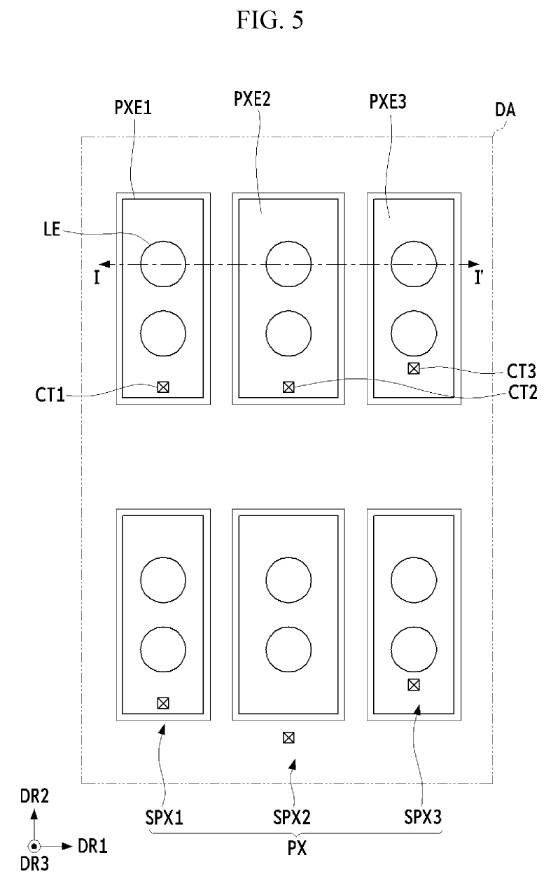

FIG. 5 is a layout drawing illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. The first color light may be light in a blue wavelength band, the second color light may be light in a red wavelength band, and the third color light may be light in a green wavelength band. For example, the blue wavelength band may refer to light having a main peak wavelength in the wavelength band from approximately 370nm to approximately 460nm, the green wavelength band may refer to light having a main peak wavelength in the wavelength band from approximately 480nm to approximately 560nm, and the red wavelength band may refer to light having a main peak wavelength in the wavelength band from approximately 600nm to approximately 750nm.

Alternatively, if each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1 and a plurality of light-emitting elements LE. The second sub-pixel SPX2 includes a second pixel electrode PXE2 and a plurality of light-emitting elements LE. The third sub-pixel SPX3 includes a third pixel electrode PXE3 and a plurality of light-emitting elements LE.

The light-emitting element LE1 of the first sub-pixel SPX1 may emit light of a first color, the light-emitting element LE2 of the second sub-pixel SPX2 may emit light of a second color, and the light-emitting element LE3 of the third sub-pixel SPX3 may emit light of a third color.

Each of the first pixel electrode PXE1, the second pixel electrode PXE2, and the third pixel electrode PXE3 may have a rectangular planar shape having a short side in a first direction DR1 and a long side in a second direction DR2. The area of the first sub-pixel SPX1, the area of the second sub-pixel SPX2, and the area of the third sub-pixel SPX3 may be set according to the light-emitting efficiency of the light-emitting element LE included in each sub-pixel SPX. For example, the area of the sub-pixel may be larger as the light conversion efficiency is lower.

For example, as shown in FIG. 5, if the light-emitting efficiency of the light-emitting element LE2 of the second sub-pixel SPX2 is lower than the light-emitting efficiency of the light-emitting element LE1 of the first sub-pixel SPX1 and the light-emitting element LE2 of the third sub-pixel SPX2, the area of the second pixel electrode PXE2 may be larger than the area of the first pixel electrode PXE1 and larger than the area of the third pixel electrode PXE2.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

A plurality of light-emitting elements LE may be arranged on each of the pixel electrodes PXE1, PXE2, and PXE3 (as used herein, “arrange on” may mean “above”). The same number of light-emitting elements LE may be arranged on each of the pixel electrodes PXE1, PXE2, and PXE3. For example, two light-emitting elements LE may be arranged on each of the pixel electrodes PXE1, PXE2, and PXE3. The plurality of light-emitting elements LE may emit light of a third color (e.g., light in a blue wavelength band), but the present disclosure is not limited thereto.

Each of the plurality of light-emitting elements LE may have a circular planar shape, but the present disclosure is not limited thereto. For example, each of the plurality of light-emitting elements LE may have a rectangular planar shape.

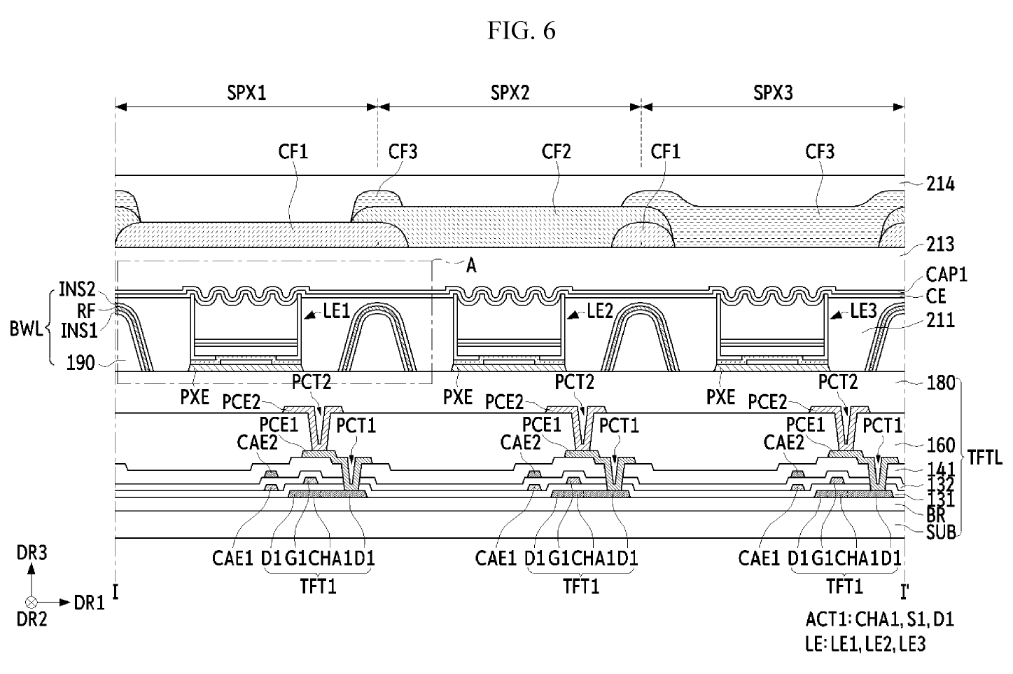

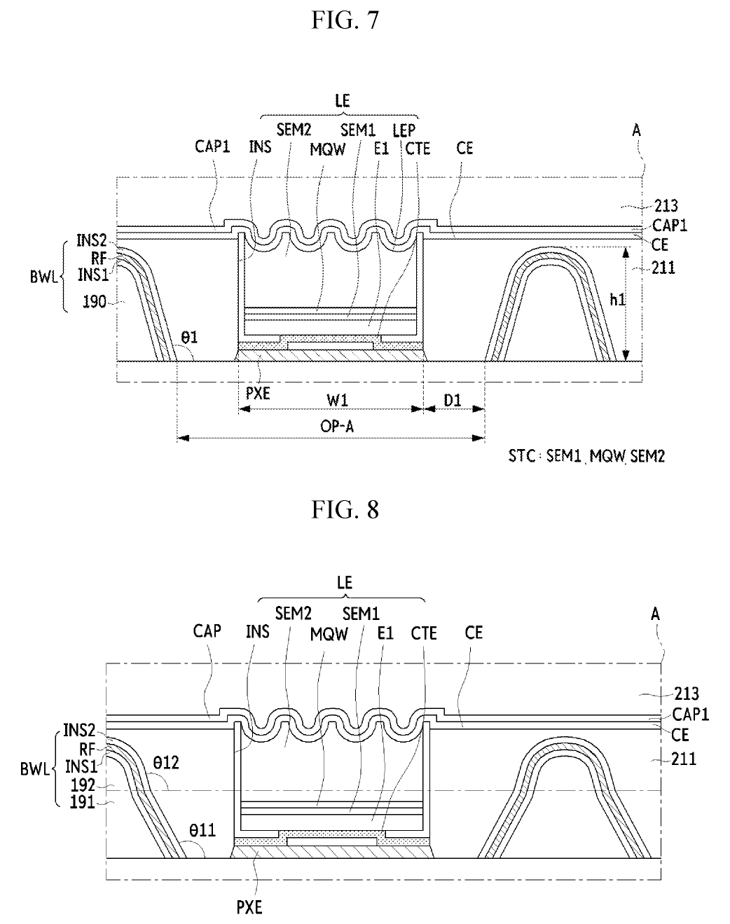

FIG. 6 is a cross-sectional view illustrating one example of a cross-section of a display panel taken along the line I-I’ in FIG. 5. FIG. 7 is a cross-sectional view illustrating one example of area A of FIG. 6 in detail.

Referring to FIGS. 6 and 7, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be arranged on the substrate SUB. The barrier film BR is a film that protects a thin-film transistor layer TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may be, for example, either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate-insulating film 131 may be arranged on the first channel area CHA1, the first source area S1, and the first drain area D1 of the thin film transistor TFT1.

A first gate metal layer may be arranged on the first gate-insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart from each other in FIG. 6, the first gate electrode G1 and the first capacitor electrode CAE1 may be connected to each other.

A second gate-insulating film 132 may be arranged on the first gate electrode G1 and the first capacitor electrode CAE1 of the thin film transistor TFT1.

A second gate metal layer may be arranged on the second gate-insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate-insulating film 132 has a dielectric constant (e.g., predetermined dielectric constant), the capacitor (C1 in FIG. 4) may be formed by the first capacitor electrode CAE1, the second capacitor electrode CAE2, and the second gate-insulating film 132 arranged between them.

A first interlayer insulating film 141 may be arranged on the second capacitor electrode CAE2.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate-insulating film 131, the second gate-insulating film 132, and the first interlayer insulating film 141.

A first planarization organic film 160 may be arranged on the first source connection electrode PCE1 to planarize a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole PCT2 penetrating the first planarization organic film 160.

A second planarization organic film 180 may be arranged on the second source connection electrode PCE2.

The barrier film BR, the first gate-insulating film 131, the second gate-insulating film 132, the third gate-insulating film 133, and the first interlayer insulating film 141 may be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

The first planarization organic film 160 and the second planarization organic film 180 may be formed of an organic insulating film, such as an acrylic resin, an epoxy resin, a phenolic resin, a polyamide resin, or a polyimide resin.

A light-emitting element layer may be arranged on the second planarization organic film 180. The light-emitting element layer may include pixel electrodes PXE1, PXE2, and PXE3, light-emitting elements LE, a common electrode CE, and a first organic layer 190.

A pixel electrode layer and the first organic layer 190 may be arranged on a second planarization organic film 180. The pixel electrode layer may include a first pixel electrode PXE1, a second pixel electrode PXE2, and a third pixel electrode PXE3. Each of the pixel electrodes PXE1, PXE2, and PXE3 may be connected to a second source connection electrode PCE2 through a connection hole (CT1/CT2/CT3 of FIG. 5) penetrating the second planarization organic film 180. Each of the pixel electrodes PXE1, PXE2, and PXE3 may be connected to a first source region S1 or a first drain region D1 of a thin film transistor TFT1 through the first source connection electrode PCE1 and the second source connection electrode PCE2. Thus, a voltage controlled by the thin film transistor TFT1 may be applied to each of the pixel electrodes PXE1, PXE2, and PXE3.

The pixel electrodes PXE1, PXE2, and PXE3 may be formed of a single layer or multiple layers made of one or an alloy of molybdenum (Mo), aluminum (Al), chromium (Cr), gold (Au), titanium (Ti), nickel (Ni), neodymium (Nd), or copper (Cu). For example, the pixel electrode layer may be made of copper (Cu) having low surface resistance to lower the resistance of each of the pixel electrodes PXE1, PXE2, and PXE3. Further, the pixel electrodes PXE1, PXE2, and PXE3 may include a first layer made of one or an alloy of molybdenum (Mo), aluminum (Al), chromium (Cr), gold (Au), titanium (Ti), nickel (Ni), neodymium (Nd), or copper (Cu) at the bottom, and a second layer made of a metal material having a high reflectivity, such as aluminum (Al), on the first layer, if the pixel electrodes PXE1, PXE2, and PXE3 are formed in a multilayer structure.

An organic partition wall (e.g., reflective structure) BWL may be formed on the second planarization organic film 180 with a first inclination angle θ1 and a first height h1 (as used herein, “formed on” may mean “above”). The lower end of the organic partition wall BWL may be located lower than the bottom of the light-emitting element LE.

When the upper end of the organic partition wall BWL is formed lower than the light-emitting element LE, then the light-emitting element LE may be suitably transferred during the light-emitting element LE transfer process.

The first inclination angle may be about 120 degrees to about 135 degrees. The first height h1 may be about 5 μm to about 8 μm, but is not limited thereto.

The organic partition wall BWL may define a first opening area OP-A. The first opening area OP-A may expose the second planarization organic film 180, which is a lower layer, and the pixel electrodes PXE1, PXE2, and PXE3. The area exposed by the first opening area OP-A may be wider than the area of the light-emitting element LE.

The organic partition wall BWL may include an organic layer 190 defining the shape of the partition wall, a first protective film INS1 covering the organic layer 190, a reflective film RF, and a second protective film INS2.

The upper end of the organic layer 190 may be higher than the active layer MQW of the light-emitting element LE and lower than the upper end of the light-emitting element LE.

The organic layer 190 may be formed of an organic material, such as an acrylic resin, an epoxy resin, a phenolic resin, a polyamide resin, a polyimide resin, or the like.

The first protective film INS1 is arranged outside the organic layer 190. The first protective film INS1 may cover the entire organic layer 190.

The reflective film RF is arranged outside the first protective film INS1.

The second protective film INS2 is arranged on top of the reflective film RF. The reflective film RF is surrounded by the first protective film INS1 and the second protective film INS2.

The reflective film RF may be spaced apart from the light-emitting element LE in a plane, and may have a closed loop shape that surrounds the sides of the light-emitting element LE. The upper end of the reflective film RF may be arranged higher than the active layer MQW of the light-emitting element LE. The lower end of the reflective film RF may be arranged lower than the light-emitting element LE. The reflective film RF may include a metal material having a high reflectivity, such as aluminum (Al).

The reflective film RF may reflect light traveling in a lateral direction from the light-emitting element LE, and may emit light to the top surface of the light-emitting element LE. Therefore, because the light loss of the light-emitting element LE may be reduced, the light efficiency of the light-emitting element LE may be increased.

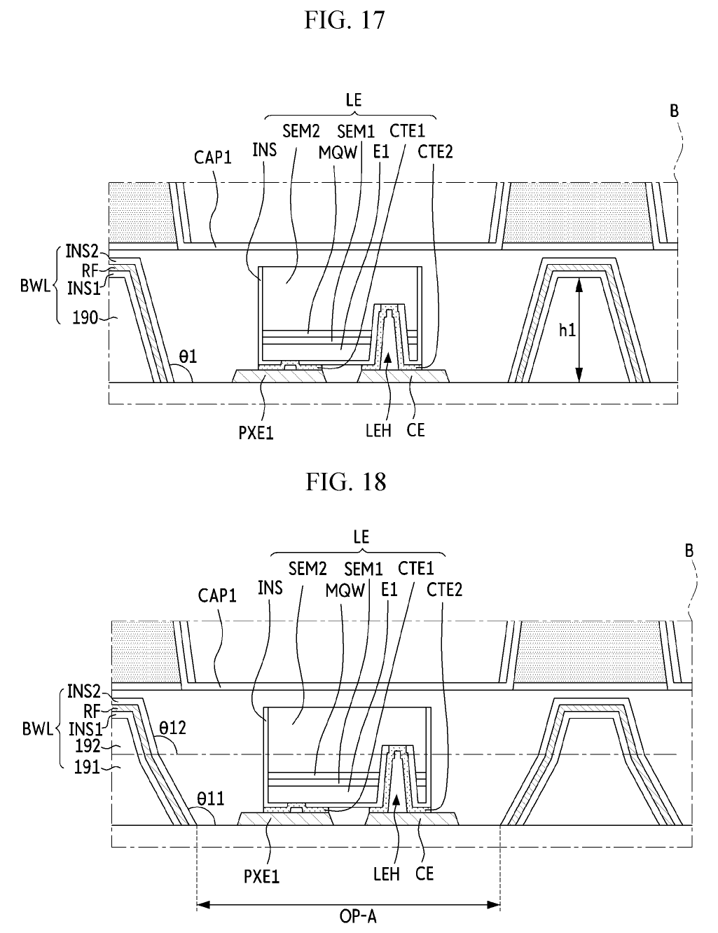

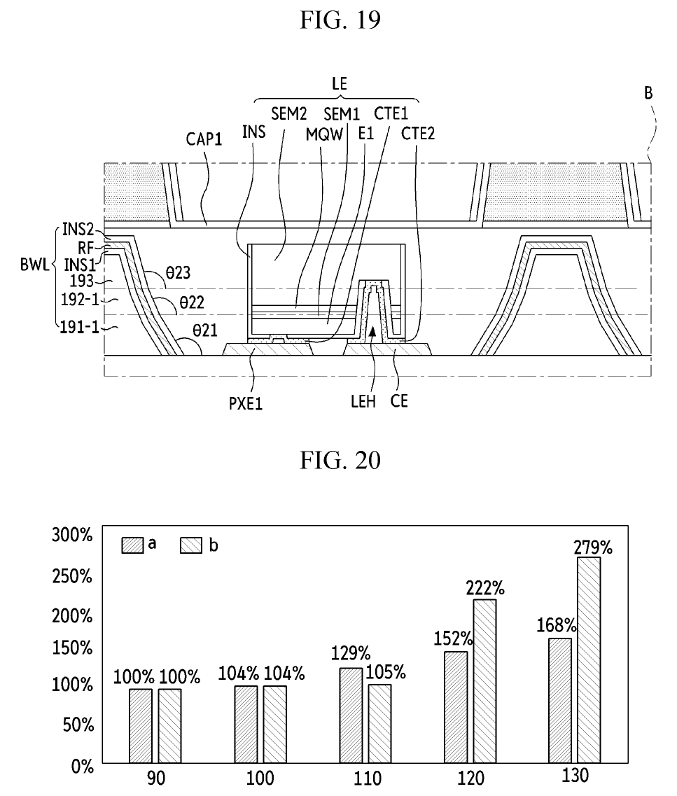

The greater the slope θ1 of the reflective film RF, the higher the front light emission efficiency may be, but the greater the slope θ1 of the reflective film RF, the wider the width of the organic layer 190. Therefore, the slope θ1 of the reflective film RF may be, for example, about 120° to about 130°. This will be described in detail with reference to FIGS. 18 and 19.

The first protective film INS1 and the second protective film INS2 may be formed of an inorganic film, such as silicon nitride (SiNₓ), silicon oxide nitride (SiON), silicon oxide (SiOₓ), titanium oxide (TiOₓ), or aluminum oxide (AlOₓ).

A plurality of light-emitting elements LE may be arranged on the pixel electrodes PXE1, PXE2, and PXE3. In FIG. 6 and FIG. 7, each of the plurality of light-emitting elements LE is shown as a vertical type micro LED extending in the third direction DR3. The vertical type micro LED refers to an LED having a structure in which a first semiconductor layer SEM1, an active layer MQW, and a second semiconductor layer SEM2 are sequentially arranged in the third direction DR3, which is a vertical direction.

The light-emitting element LE may include a substantially vertical side surface as shown in FIG. 7. For example, the light-emitting element LE may be patterned through vertical etching and may have a rectangular or square cross-sectional shape in which the width of the top surface and the width of the bottom surface are substantially the same. The shape of the light-emitting element LE may be variously changed according to embodiments. For example, the light-emitting element LE may have an inverted taper cross-sectional shape. For example, the light-emitting element LE may have an inverted trapezoidal cross-sectional shape in which the width of the top surface is wider than the width of the bottom surface.

Each of the plurality of light-emitting elements LE may be formed of an inorganic material, such as gallium nitride (GaN). Each of the plurality of light-emitting elements LE may have a length in the first direction DR1, a length in the second direction DR2, and a length in the third direction DR3 of several to several hundred μm, respectively. For example, each of the plurality of light-emitting elements LE may have a length in the first direction DR1, a length in the second direction DR2, and a length in the third direction DR3 of approximately 6 μm to approximately 10 μm or less.

Each of the plurality of light-emitting elements LE may be formed by growing on a semiconductor substrate, such as a silicon substrate or a sapphire substrate. The plurality of light-emitting elements LE may be transferred directly from the semiconductor substrate onto the pixel electrodes PXE1, PXE2, and PXE3 of the display panel 100. Alternatively, the plurality of light-emitting elements LE may be transferred onto the pixel electrodes PXE1, PXE2, and PXE3 of the display panel 100 by an electrostatic method using an electrostatic head or a stamp method using an elastic polymer material, such as PDMS or silicon as a transfer substrate.

The light-emitting element LE may include a conductive layer E1, a semiconductor stack STC, a contact electrode CTE, and an insulating layer INS. The semiconductor stack STC may include a first semiconductor layer SEM1, an active layer MQW, and a second semiconductor layer SEM2 sequentially arranged in a third direction DR3.

The conductive layer E1 may be arranged on the bottom surface of the first semiconductor layer SEM1. In FIG. 7, the conductive layer E1 is illustrated as covering the entire bottom surface of the first semiconductor layer SEM1, but the present disclosure is not limited thereto. For example, the conductive layer E1 may be arranged on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), or copper (Cu).

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), etc., for example, gallium nitride (GaN).

The active layer MQW may be arranged on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group three to Group five semiconductor materials according to the wavelength range of emitted light.

In one or more embodiments, if the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt% to approximately 20 wt%.

The second semiconductor layer SEM2 may be arranged on the first semiconductor layer SEM1. The second semiconductor layer SEM2 may be a semiconductor material layer doped with a second conductivity type dopant, such as silicon (Si), germanium (Ge), tin (Sn), etc., for example, gallium nitride (GaN).

An electron-blocking layer may be arranged between the first semiconductor layer SEM1 and the active layer MQW. The electron-blocking layer may be a layer to suppress or prevent too many electrons from flowing into the active layer MQW. For example, the electron-blocking layer may be aluminum gallium nitride (AlGaN) or p-type aluminum gallium nitride (AlGaN) doped with p-type magnesium (Mg). The electronic blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

A light extraction patterns LEP may be formed on a top surface of the semiconductor stack STC. For example, light extraction patterns LEP may be formed on the top surface of the second semiconductor layer SEM2. The light extraction patterns LEP may be patterns for increasing the efficiency of light emitted from the top surface of the light-emitting element LE. The light extraction patterns LEP may be concave patterns formed in a hemisphere or a semi-ellipse.

The protective film INS may be a film for protecting the bottom surface and the side surface of the light-emitting element LE. The protective film INS may be arranged on the bottom surface and the side surface of the conductive layer E1 and the side surface of the semiconductor stack STC. For example, the protective film INS may be arranged on the bottom surface and the side surface of the conductive layer E1, the side surface of the first semiconductor layer SEM1, the side surface of the active layer MQW, and the side surface of the second semiconductor layer SEM2. The protective film INS may be formed of an inorganic film, such as silicon nitride (SiNₓ), silicon oxide nitride (SiON), silicon oxide (SiOₓ), titanium oxide (TiOₓ), or aluminum oxide (AlOₓ).

The contact electrode CTE may be arranged on the protective film INS. The contact electrode CTE may be arranged between the pixel electrodes PXE1, PXE2, and PXE3 and the protective film INS. The contact electrode CTE may contact the pixel electrodes PXE1, PXE2, and PXE3.

The contact electrode CTE may be connected to the exposed conductive layer E1 that is not covered by the protective film INS. The contact electrode CTE may include one of molybdenum (Mo), aluminum (Al), chromium (Cr), gold (Au), titanium (Ti), nickel (Ni), neodymium (Nd), or copper (Cu). For example, the plurality of contact electrode CTE may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The distance D1 between the light-emitting element LE and the organic partition wall BWL may be less than the width W1 of the light-emitting element LE.

The second organic layer 211 may be arranged to cover the side surfaces of the plurality of light-emitting elements LE. The second organic layer 211 is a layer for flattening the steps caused by the plurality of light-emitting elements LE. The height of the second organic layer 211 may be arranged to cover most of the side surfaces of each of the plurality of light-emitting elements LE, but in one or more other embodiments, it may be arranged to cover the side surfaces of each of the light-emitting elements LE by a plurality of organic films. The second organic layer 211 may be formed of an organic film, such as an acrylic resin, epoxy resin, phenolic resin, polyamide resin, polyimide resin, or the like.

A common electrode CE may be arranged on the top surface of each of the plurality of light-emitting elements LE and the top surface of the second organic layer 211. The common electrode CE may be a common layer formed commonly on the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO) that may transmit light.

The pixel electrodes PXE1, PXE2, and PXE3 may be referred to as an anode electrode or a first electrode, and the common electrode CE may be referred to as a cathode electrode or a second electrode.

A first capping layer CAP1 may be arranged on the common electrode CE. The first capping layer CAP1 may serve to encapsulate a lower component. The first capping layer CAP1 may be formed of an inorganic film, such as silicon nitride (SiNₓ), silicon oxide nitride (SiON), silicon oxide (SiOₓ), titanium oxide (TiOₓ), or aluminum oxide (AlOₓ).

A third organic layer 213 may be located on the first capping layer CAP1 (as used herein, “located on” may mean “above”). A plurality of color filters CF1, CF2, and CF3 may be arranged on the third organic layer 213. The plurality of color filters CF1, CF2, and CF3 may include first color filters CF1, second color filters CF2, and/or third color filters CF3.

The first color filter CF1 arranged on the first sub-pixel SPX1 may transmit first light (light in a blue wavelength band). Therefore, the first sub-pixel SPX1 may emit the first light (light in the blue wavelength band).

The second color filter CF2 arranged in the second sub-pixel SPX2 may transmit the second light (light in the red wavelength band). Therefore, the second sub-pixel SPX2 may emit the second light (light in the red wavelength band).

The third color filter CF3 arranged in the third sub-pixel SPX3 may transmit the third light (light in the green wavelength band). Therefore, the third sub-pixel SPX3 may emit the third light (light in the green wavelength band).

The first color filter CF1, the second color filter CF2, and the third color filter CF3 overlapping in the third direction DR3 may overlap the organic partition wall BWL in the third direction DR3.

A fourth organic film 214 for planarization may be placed on a plurality of color filters CF1, CF2, and CF3.

The third organic layer 213 and the fourth organic film 214 may be formed from an acrylic resin, an epoxy resin, a phenolic resin, a polyamide resin, a polyimide resin, or the like.

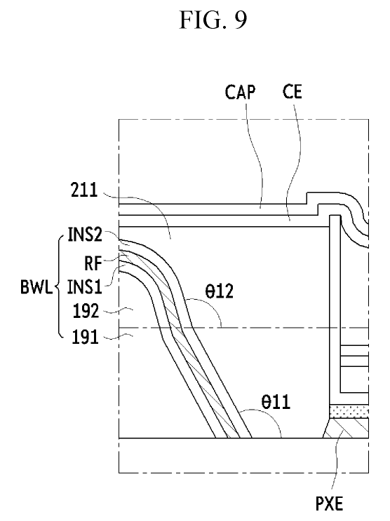

FIG. 8 is a cross-sectional view illustrating another example of area A of FIG. 6 in detail. FIG. 9 is an enlarged view of a portion of FIG. 8.

The embodiments of FIGS. 8 and 9 differ from the one or more embodiments corresponding to FIG. 7 in that the organic partition wall BWL includes a first organic layer 191 and a second organic layer 192. In FIGS. 8 and 9, descriptions that overlap with the one or more embodiments corresponding to FIG. 7 will be omitted, and differences from the one or more embodiments corresponding to FIG. 7 will be mainly described.

Referring to FIGS. 8 and 9, the organic partition wall BWL may include a first organic layer 191 and a second organic layer 192 arranged on the first organic layer 191. The first organic layer 191 and the second organic layer 192 have different inclinations.

An inclination angle θ11 of the first organic layer 191 may be greater than a second inclination angle θ12 of the second organic layer 192. For example, the inclination angle θ11 of the first organic layer 191 is about 120 degrees or more, and the second inclination angle θ12 of the second organic layer 192 is about 120 degrees or less. Further, the average of the inclination angle θ11 of the first organic layer 191 and the second inclination angle θ12 of the second organic layer 192 may be about 120 degrees or more. For example, the average of the inclination angle θ11 of the first organic layer 191 and the second inclination angle θ12 of the second organic layer 192 may be about 120 degrees to about 135 degrees.

The inflection point of the inclination angle θ11 of the first organic layer 191 and the second inclination angle θ12 of the second organic layer 192 may be located higher than the active layer MQW of the light-emitting element LE. Therefore, the upper portion of the active layer MQW may be positioned lower than the upper portion of the first organic layer 191.

Because the organic partition wall BWL has a three-layer structure of a first protective film INS1, a reflective film RF, and a second protective film INS2 on (outside) the first organic layer 191 and the second organic layer 192, for convenience of explanation, the reflective film RF arranged on the outside of the first organic layer 191 is referred to as the first reflective film, and the reflective film RF arranged on the outside of the second organic layer 192 is referred to as the second reflective film. In addition, the inclination angle θ11 of the first reflective film is the same as that of the first organic layer 191, and the inclination angle θ12 of the second reflective film is the same as that of the second organic layer 192.

Therefore, the average angle of the inclination angle θ11 of the first reflective film and the second inclination angle θ12 of the second reflective film is about 120 degrees or more, for example about 120 to about 135 degrees. Furthermore, the inclination angle θ11 of the first reflective film is greater than the inclination angle θ12 of the second reflective film. For example, the inclination angle θ11 of the first reflective film may be about 120 degrees or more, and the inclination angle θ12 of the second reflective film may be about 120 degrees or less.

In addition, the inflection point of the inclination angle θ11 of the first reflective film and the second inclination angle θ12 of the second reflective film may be positioned higher than the active layer MQW of the light-emitting element LE. Therefore, the upper portion of the active layer MQW may be positioned lower than the upper portion of the first reflective film.

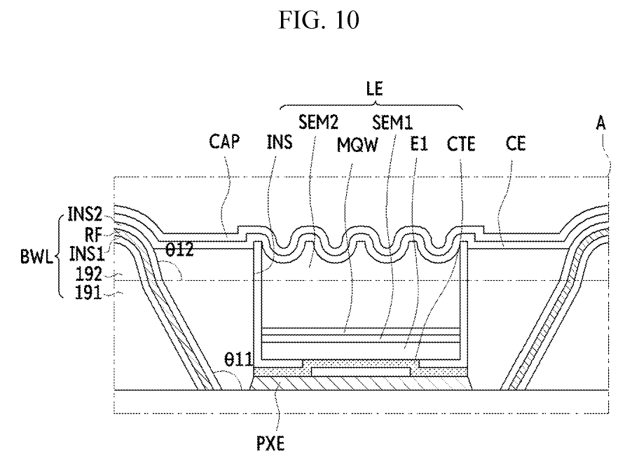

FIG. 10 is a cross-sectional view illustrating another example of area A of FIG. 6 in detail according to one or more other embodiments.

Referring to FIG. 10, the upper portion of the organic partition wall BWL is higher than the upper portion of the light-emitting element LE, which is different from the one or more embodiments corresponding to FIG. 8. In FIG. 10, descriptions that overlap with the one or more embodiments corresponding to FIG. 8 will be omitted, and differences from the one or more embodiments corresponding to FIG. 8 will be mainly described.

Referring to FIG. 10, the organic partition wall BWL may include a first organic layer 191, and a second organic layer 192 arranged on the first organic layer 191.

The first organic layer 191 has a first inclination angle θ11, which is formed by the outer surface and the bottom surface, of about 120 degrees or more. The second organic layer 192 has a second inclination angle θ12, which is formed by the outer surface and the bottom surface, of about 120 degrees or more but smaller than the first inclination angle, and the average of the first inclination angle θ11 and the second inclination angle θ12 is about 120 degrees or more. The first organic layer 191 and the inflection point of the first organic layer 191 are positioned higher than the top of the active layer MQW. Therefore, the top of the first organic layer 191 is positioned higher than the top of the active layer MQW.

The upper end of the first organic layer 191 may be positioned higher than the upper end of the active layer MQW, and the upper end of the second organic layer 192 may be positioned higher than the upper end of the light-emitting element LE. Thus, the upper end of the reflective film RF positioned on the outside of the first organic layer 191 and the second organic layer 192 may be positioned higher than the light-emitting element LE. Therefore, the reflective film RF may surround all sides of the light-emitting element LE.

In one or more embodiments, if the top of the organic partition wall BWL is formed higher than the top of the light-emitting element LE, the reflective film RF arranged on the outside of the organic partition wall BWL is positioned higher than the top of the light-emitting element LE, which may effectively reflect light traveling in the lateral direction of the light-emitting element LE to the front surface.

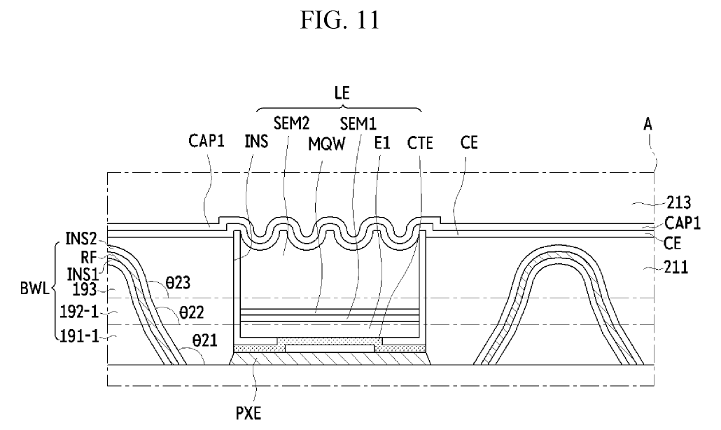

FIG. 11 is a cross-sectional view illustrating another example of area A of FIG. 6 in detail.

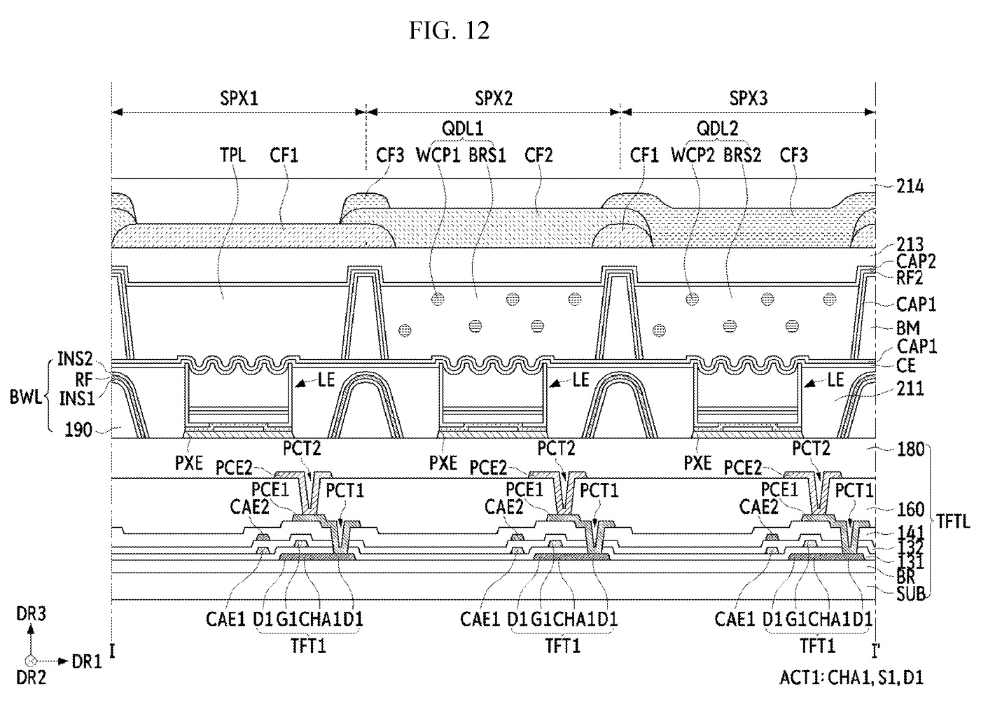

The one or more embodiments corresponding to FIG. 11 differs from the one or more embodiments corresponding to FIG. 7 in that the organic partition wall BWL includes a first organic layer 191-1, a second organic layer 192-1, and a third organic layer 193. In FIG. 12, descriptions that overlap with the one or more embodiments corresponding to FIG. 7 will be omitted, and differences from the one or more embodiments corresponding to FIG. 7 will be mainly described.

Referring to FIG. 11, the organic partition wall BWL may include a first organic layer 191-1, and a second organic layer 192-1 arranged on the first organic layer 191-1. In addition, the organic partition wall BWL may further include a third organic layer 193 arranged on the second organic layer 192-1.

The first organic layer 191-1, the second organic layer 192-1, and the third organic layer 193 have different slopes. The slope of the organic layer arranged at or closer to the bottom (e.g., the slope of the first organic layer 191-1) may be greater. For example, the inclination angle θ21 of the first organic layer 191-1 may be greater than the inclination angle θ22 of the second organic layer 192-1, and the inclination angle θ22 of the second organic layer 192-1 may be greater than the inclination angle θ23 of the third organic layer 193.

The average of the inclination angles of the plurality of organic layers may be about 120 degrees or more, and for example, may be about 120 degrees to about 135 degrees. For example, the average of the inclination angle θ21 of the first organic layer 191-1, the inclination angle θ22 of the second organic layer 192-1, and the inclination angle θ23 of the third organic layer 193 may be about 120 degrees or more, and for example may be about 120 degrees to about 135 degrees.

In a display device according to various embodiments, there is no reflective layer directly arranged on the light-emitting element LE, and the bottom of the reflective film RF in the organic partition wall BWL is positioned lower than the bottom of the light-emitting element LE, so the organic partition wall BWL may effectively reflect the side light of the light-emitting element LE.

In addition, the average inclination angle of the organic partition wall BMW is greater than about 120 degrees, which may improve LEE (light extraction efficiency) (a), luminance (b), and frontal light emission efficiency. This will be described in detail with reference to FIGS. 18 and 19.

LEE (light extraction efficiency) is a value indicating how much light from the light-emitting element may be extracted and refers to light extraction efficiency.

FIG. 12 is a cross-sectional view illustrating an example of a cross-section of a display panel taken along the line I-I’ of FIG. 5 according to one or more other embodiments.

FIG. 12 is different from the one or more embodiments corresponding to FIG. 6 in that the light-emitting element LE emits light in a blue wavelength band, and a light conversion layer QDL1 and QDL2 or a light transmission layer TPL is arranged on the light-emitting element LE. In FIG. 11, overlapping descriptions with the one or more embodiments corresponding to FIG. 6 are omitted and differences from the one or more embodiments corresponding to FIG. 6 are mainly described.

Referring to FIG. 12, the light-emitting elements LE arranged in the first sub-pixel SPX1, the second sub-pixel SPX1, and the second sub-pixel SPX3 may emit light in a blue wavelength.

A light-blocking layer BM, a light transmission layer TPL, a first light conversion layer QDL1, and a second light conversion layer QDL2 may be arranged on the first capping layer CAP1. The light transmission layer TPL, the first light conversion layer QDL1, and the second light conversion layer QDL2 may be formed by compartment of the light-blocking layer BM. Thus, the light transmission layer TPL may be arranged on the first capping layer CAP1 in the first sub-pixel SPX1, the first light conversion layer QDL1 may be arranged on the first capping layer CAP1 in the second sub-pixel SPX2, and the second light conversion layer QDL2 may be arranged on the first capping layer CAP1 in the third sub-pixel SPX3. The light-blocking layer BM may not overlap with the plurality of light-emitting elements LE in the third direction DR3.

The light transmission layer TPL may include a light transmitting organic material. The light transmission layer TPL may transmit light of a blue wavelength band incident from the light-emitting element LE to one surface of the light transmission layer TPL.

The first light conversion layer QDL1 may convert a portion of the light in the blue wavelength band incident from the light-emitting element LE into light in the red wavelength band. The first light conversion layer QDL1 may include a first base resin BRS1 and a first wavelength conversion particle WCP1. The first base resin BRS1 may include a light transmitting organic material. The first wavelength conversion particle WCP1 may convert a portion of the light in the blue wavelength band incident from the light-emitting element LE into light in the red wavelength band.

The second light conversion layer QDL2 may convert a portion of the light in the blue wavelength band incident from the light-emitting element LE into light in the green wavelength band. The second light conversion layer QDL2 may include a second base resin BRS2 and a second wavelength conversion particle WCP2. The second base resin BRS2 may include a light-transmitting organic material. The second wavelength conversion particle WCP2 may convert a portion of the light of the blue wavelength band incident from the light-emitting element LE into light of the green wavelength band.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light-blocking layer BM may be formed from an organic film, such as an acrylic resin, epoxy resin, phenolic resin, polyamide resin, polyimide resin, or the like. The light-blocking layer BM may include a light-blocking material to reduce or prevent light of the light-emitting element LE of one sub-pixel from propagating to an adjacent sub-pixel. For example, the light-blocking layer BM may include an inorganic black pigment, such as carbon black or an organic black pigment.

In FIG. 12, the light-blocking layer BM is formed as a single layer, but is not limited thereto, and may be formed as a multilayer layer as suitable.

A reflective film RF may be arranged between the light-blocking layer BM and the first light conversion layer QDL1, between the light-blocking layer BM and the second light conversion layer QDL2, and between the light-blocking layer BM and the light transmission layer TPL.

The reflective film RF may include a metal material having a high reflectivity, such as aluminum (Al). The thickness of the reflective film RF may be approximately 0.1 μm. Alternatively, the reflective film RF may include a first layer and a second layer of M pairs (M is an integer greater than or equal to 2) having different refractive indices to function as distributed Bragg reflectors (DBR). In this case, the M first layers and the M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be arranged on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A third organic layer 213 may be arranged on the second capping layer CAP2. A plurality of color filters CF1, CF2, and CF3 may be arranged on the third organic layer 213.

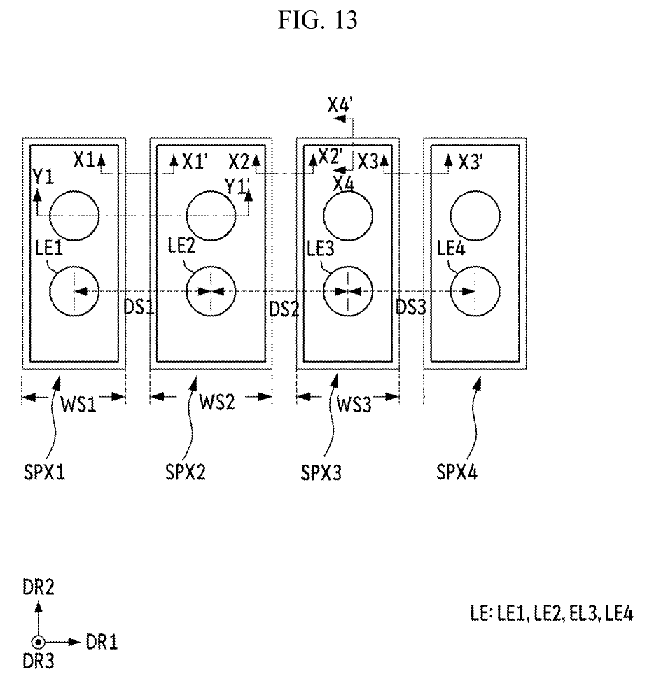

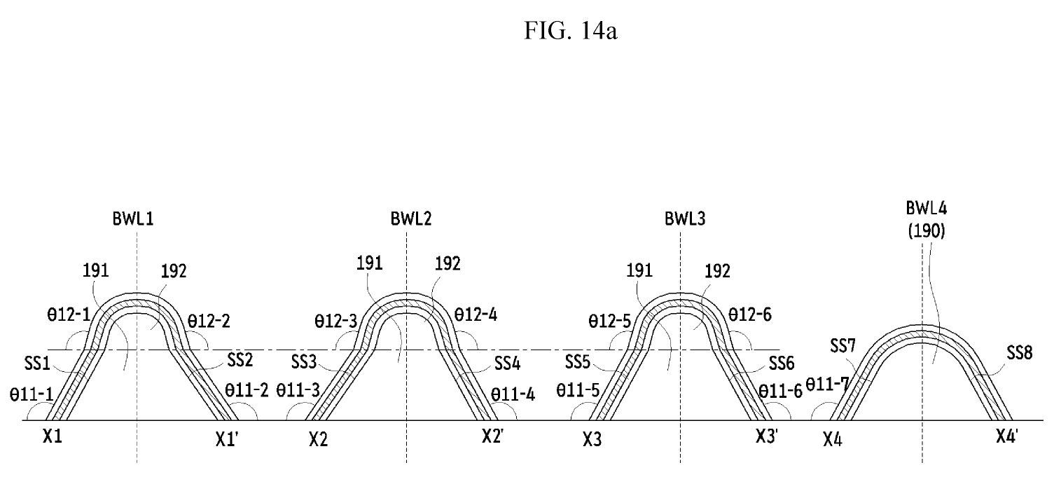

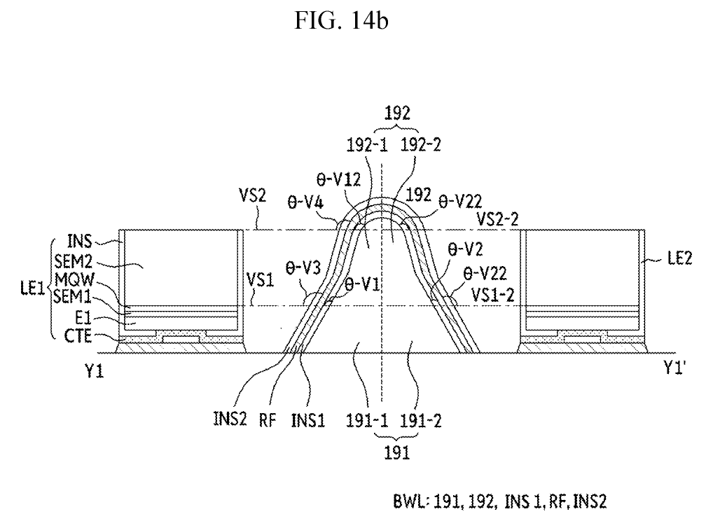

FIG. 13 is a layout diagram illustrating pixels of a display area according to one or more other embodiments. FIG. 14a is a cross-sectional view illustrating an example of an organic partition taken along the line X1-X1’, the line X2-X2’, the line X3-X3’, and the line X4-X4’ of FIG. 13, and FIG. 14b is a cross-sectional view illustrating an example of an organic partition wall taken along the line Y1-Y1’ of FIG. 13 according to one or more other embodiments.

Referring to FIG. 13, a first sub-pixel SPX1, a second sub-pixel SPX2, a third sub-pixel SPX3, and a fourth sub-pixel SPX4 may be arranged in a first direction.

The first sub-pixel SPX1 may include a first light-emitting element LE1 that emits blue light, the second sub-pixel SPX2 may include a second light-emitting element LE2 that emits red light, the third sub-pixel SPX3 may include a third light-emitting element LE3 that emits green light, and the fourth sub-pixel SPX4 may include a fourth light-emitting element LE4 that emits blue light.

The distances from the centers of each of the first sub-pixel SPX1, the second sub-pixel SPX2, the third sub-pixel SPX3, and the fourth sub-pixel SPX4 to the centers of neighboring sub-pixels may be the same. For example, the distance DS1 from the center of the width in the first direction DR1 of the first sub-pixel SPX1 to the center of the width in the first direction DR1 of the second sub-pixel SPX2 and the distance DS2 from the center of the width in the first direction DR1 of the second sub-pixel SPX2 to the center of the width in the first direction DR1 of the third sub-pixel SPX3 are the same. Also, the distance DS2 from the center of the width in the first direction DR1 of the second sub-pixel SPX2 to the center of the width in the first direction DR1 of the third sub-pixel SPX3 and the distance DS2 from the center of the width in the first direction DR1 of the third sub-pixel SPX3 to the center of the width in the first direction DR1 of the neighboring fourth sub-pixel SPX4 are the same.

The width WS2 of the first direction DR1 of the second sub-pixel SPX2 including the second light-emitting element LE2 having the lowest light-emitting efficiency is wider than the width WS1 of the neighboring first sub-pixel SPX1 and the width WS3 of the third sub-pixel SPX3.

Accordingly, the inclination angle θ11-2 of the first organic layer 191 of the organic partition wall BWL1 facing the second sub-pixel SPX2 may be larger than the inclination angle θ11-1 of the first organic layer 191 of the organic partition wall BWL1 facing the first sub-pixel SPX1 and may also be larger than the inclination angle θ11-3 of the organic partition wall BWL2 facing the second sub-pixel SPX2.

For example, referring to FIG. 14a, the organic partition wall BWL1 between the first sub-pixel SPX1 and the second sub-pixel SPX2 is asymmetrical left and right based on the central axis extending in the third direction DR3.

The inclination angle θ11-1 between the outer surface SS1 and the lower surface of the first organic layer 191 facing the first sub-pixel SPX1 may be approximately 130 degrees, and the inclination angle θ11-2 between the outer surface SS2 and the lower surface of the first organic layer 191 facing the second sub-pixel SPX2 may be approximately 132 degrees. Further, the inclination angle θ12-1 between the outer surface SS1 and the lower surface of the second organic layer 192 may be approximately 115 degrees, and the inclination angle θ12-2 between the outer surface SS2 and the lower surface of the second organic layer 192 facing the second sub-pixel SPX2 may be approximately 113 degrees.

The organic partition wall BWL2 between the second sub-pixel SPX2 and the third sub-pixel SPX3 is asymmetrical left and right based on the central axis extending in the third direction DR3.

The inclination angle θ11-3 between the outer surface SS3 and the lower surface of the first organic layer 191 facing the second sub-pixel SPX2 is approximately 132 degrees, and the inclination angle θ11-4 between the outer surface SS4 and the lower surface of the first organic layer 191 facing the third sub-pixel SPX3 is approximately 130 degrees. Also, the inclination angle θ12-3 between the outer surface SS3 and the lower surface of the second organic layer 192 facing the second sub-pixel SPX2 may be approximately 113 degrees, and the inclination angle θ12-4 between the outer surface SS4 and the lower surface of the second organic layer 192 facing the third sub-pixel SPX3 may be approximately 115 degrees.

The organic partition wall BWL3 between the third sub-pixel SPX3 and the fourth sub-pixel SPX4 is symmetrical left and right based on the central axis extending in the third direction DR3.

The inclination angle θ11-5 between the outer surface SS5 and the lower surface of the first organic layer 191 facing the third sub-pixel SPX3 is approximately 130 degrees, and the inclination angle θ11-6 between the outer surface SS4 and the lower surface of the first organic layer 191 facing the fourth sub-pixel SPX4 is approximately 130 degrees.

In addition, the inclination angle θ12-5 between the outer surface SS5 and the lower surface of the second organic layer 192 facing the third sub-pixel SPX3 is about 115 degrees, and the inclination angle θ12-6 between the outer surface SS4 and the lower surface of the first organic layer 191 facing the fourth sub-pixel SPX4 is about 115 degrees.

The organic partition wall BWL4 positioned in the second direction DR2 of the plurality of sub-pixels SPX1, SPX2, SPX3, and SPX4 may be formed of a single organic layer 190. Furthermore, the inclination angle θ11-7 between the outer surface SS6 and the lower surface of the sub-pixel adjacent to the organic layer 190 is about 135 degrees.

In one or more embodiments, the distance between neighboring sub-pixels may be different depending on the light emission efficiency of the sub-pixels (or the light-emitting elements LE). The light emission efficiency may be improved by forming the inclination angle of the organic partition wall BWL facing the sub-pixel with low light emission efficiency (e.g., the sub-pixel emitting red light) larger.

In addition, the organic partition wall BWL may be formed with different inclination angles depending on the distance between neighboring sub-pixels. Therefore, even one organic partition wall BWL may be formed symmetrically or asymmetrically depending on the distance between neighboring sub-pixels. Even for an organic partition wall BWL surrounding one sub-pixel, the inclination angles of the outer surface and the lower surface may be different depending on the type of neighboring sub-pixel.

FIG. 14b is a drawing to illustrate an organic partition wall BWL arranged between a first light-emitting element LE1 and a second light-emitting element LE2. FIG. 14b may correspond to different embodiments from FIG. 14a.

Referring to FIG. 14b, the first light-emitting element LE1 may include a first semiconductor layer SEM1, a first active layer MQW that emits light of a first wavelength, and a second semiconductor layer SEM2, and the second light-emitting element LE2 may include a first semiconductor layer SEM1, a second active layer MQW that emits light of a second wavelength that is different from the first wavelength, and a second semiconductor layer SEM2.

The description of the first light-emitting element LE1 and the second light-emitting element LE2 may refer to the first light-emitting element LE1 and the second light-emitting element LE2 described with reference to FIGS. 6 and 7. However, the first light-emitting element LE1 and the second light-emitting element LE2 of FIG. 14b may differ in that their upper surfaces do not have a light extraction pattern LEP.

The organic partition wall BWL may be formed higher than the neighboring light-emitting elements, as shown in FIG. 10. In one or more embodiments, other components (e.g., a common electrode CE, a first capping layer CAP1, a color filter) may be arranged on the organic partition wall BWL and the light-emitting elements LE1 and LE2, as described with reference to FIGS. 6, 7 and 10.

The organic partition wall BWL may include a first organic layer 191 and a second organic layer 192.

The first organic layer 191 may include a first inclined portion 191-1 arranged toward the first light-emitting element LE1 and a second inclined portion 191-2 arranged toward the second light-emitting element LE2.

The first inclined portion 191-1 and the second inclined portion 191-2 may be formed asymmetrically to each other.

For example, at the point where the first virtual surface VS1 and the first inclined portion 191-1 intersect, a first angle θ-V1 between the first virtual surface VS1 and the outer surface of the first inclined portion 191-1 is about 120 degrees or more. The second inclined portion 191-2 is formed at a point where the second virtual surface VS2 and the second inclined portion 191-2 intersect, and a second angle θ-V2 between the second virtual surface VS2 and the outer surface of the second inclined portion 191-2 is greater than the first angle θ-V1 by about 5 degrees or more and less than about 135 degrees. The first virtual surface VS1 may be a surface extending parallel to the boundary between the second semiconductor layer SEM2 and the first active layer MQW of the first light-emitting element LE1, and the second virtual surface VS2 may be a surface extending parallel to the boundary between the second semiconductor layer SEM2 and the second active layer MQW of the second light-emitting element LE2. The first virtual surface VS1 and the second virtual surface VS2 may be parallel to or coincide with each other.

The second organic layer 192 may include a 1-2 inclined portion 191-2 arranged toward the first light-emitting element LE1 and a 2-2 inclined portion 192-2 arranged toward the second light-emitting element LE2.

The 1-2 inclined portion 192-1 is arranged on the first inclined portion 191-1, and the 1-2 inclined portion 192-1 has a 1-2 angle θ-V12 formed by the 1-2 virtual surface VS1-1 and the outer surface of the 1-2 inclined portion 192-1 at a point where the 1-2 virtual surface VS1-1 and the 1-2 inclined portion 192-1 intersect, and the 1-2 angle θ-V12 is smaller than the first angle θ-V1, and the average of the first angle θ-V1 and the 1-2 angle θ-V12 is about 120 degrees or more. For example, the average of the first angle θ-V1 and the 1-2 angle θ-V12 is within a range of about 120 degrees to about 135 degrees.

The 1-2 virtual surface VS1-1 is a surface that extends parallel to the upper surface of the second semiconductor layer SEM2 of the first light-emitting element LE.

The upper surface of the second semiconductor layer SEM2 is a surface facing the lower surface of the second semiconductor layer SEM2, and the lower surface refers to a surface facing the first active layer MQW. That is, in the second semiconductor layer SEM2, the surface that faces the first active layer MQW is the lower surface, and the surface that is farther from the first active layer MQW is the upper surface.

The 2-2 inclined portion 192-2 is arranged on the second inclined portion 191-2, and the 2-2 inclined portion 192-2 has a 2-2 angle θ-V22 between the 2-2 virtual surface VS2-2 and the outer surface of the 2-2 inclined portion 192-2 at a point where the 2-2 virtual surface VS2-2 and the 2-2 inclined portion 192-2 intersect, and the 2-2 angle θ-V12 is smaller than the second angle θ-V2, and the average of the second angle θ-V2 and the 2-2 angle θ-V22 is about 120 degrees or more. For example, the average of the second angle θ-V2 and the 2-2 angle θ-V22 is within a range of about 120 degrees to about 135 degrees.

The organic partition wall BWL may further include a reflective film RF arranged on the outer surface of the first organic layer 191 and the second organic layer 192. The reflective film RF may have a substantially constant thickness on the outer surfaces of the first organic layer 191 and the second organic layer 192 and may have the same slope as the slopes of the first inclined portion 191-1 and the second inclined portion 191-2 of the first organic layer 191. For example, when the reflective film RF arranged on the outer surface of the first inclined portion 191-1 of the first organic layer 191 is referred to as the first reflective film for convenience of explanation, and the reflective film RF arranged on the outer surface of the second inclined portion 191-2 is referred to as the second reflective film RF, the third angle θ-V3 between the outer surface of the first reflective film and the first virtual surface VS1 may be the same as the first angle θ-V1. Similarly, the fourth angle θ-V4 between the outer surface of the second reflective film and the second virtual surface may be equal to the second angle θ-V2. The third angle θ-V3 may be about 120 degrees or more, and the fourth angle θ-V4 may be about 5 degrees or more larger than the third angle and about 135 degrees or less.

Protective films INS1 and INS2 may be further arranged on the inner and outer sides of the reflective film RF. Referring to FIG. 7, the protective films INS1 and INS2 may be illustrated.

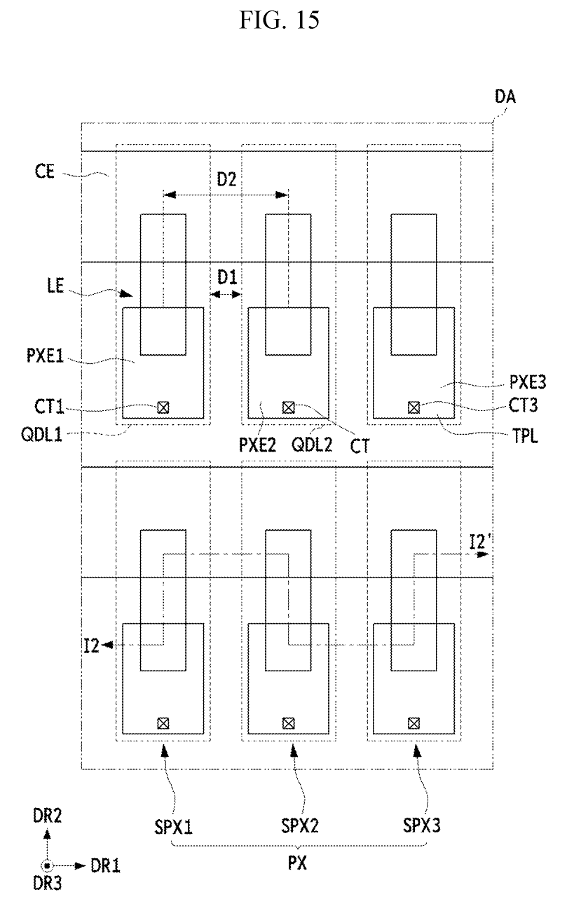

FIG. 15 is a layout diagram illustrating pixels of a display area according to one or more embodiments.

The one or more embodiments corresponding to FIG. 15 differs from the one or more embodiments corresponding to FIG. 5 in that the light-emitting elements LE are arranged on the pixel electrodes PXE1, PXE2, and PXE3 and the common electrode CE in each of the first sub-pixel SPX1, the second sub-pixel SPX2, and the third sub-pixel SPX3. In FIG. 15, descriptions that overlap with the one or more embodiments corresponding to FIG. 5 will be omitted, and differences from the one or more embodiments corresponding to FIG. 5 will be mainly described.

Referring to FIG. 15, the pixel electrodes PXE1, PXE2, and PXE3 and the common electrode CE in each of the first sub-pixel SPX1, the second sub-pixel SPX2, and the third sub-pixel SPX3 may be arranged in the second direction DR2. Each of the pixel electrodes PXE1, PXE2, and PXE3 and the common electrodes CE may have a rectangular planar shape, but the present disclosure is not limited thereto.

When the light conversion efficiency of the second light conversion layer QDL2 is lower than the light conversion efficiency of the first light conversion layer QDL1, the area of the second pixel electrode PXE2 may be larger than the area of the first pixel electrode PXE1. Also, because the light transmission layer TPL directly transmits the light of the light-emitting element LE, while the first light conversion layer QDL1 may suitably convert the light, the area of the first pixel electrode PXE1 may be larger than the area of the third pixel electrode PXE3.

The common electrode CE may be connected to the second power supply line VSL to which the second driving voltage VSS is applied. Thus, the second driving voltage VSS may be applied to each of the common electrodes CE.

In each of the first sub-pixel SPX1, the second sub-pixel SPX2, and the third sub-pixel SPX3, the pixel electrodes PXE1, PXE2, and PXE3 and the common electrode CE and the light-emitting element LE are arranged on the pixel electrodes PXE1, PXE2, and PXE3 and the common electrode CE, so that the length of the light-emitting element LE in the second direction DR2 may be longer than the length in the first direction DR1.

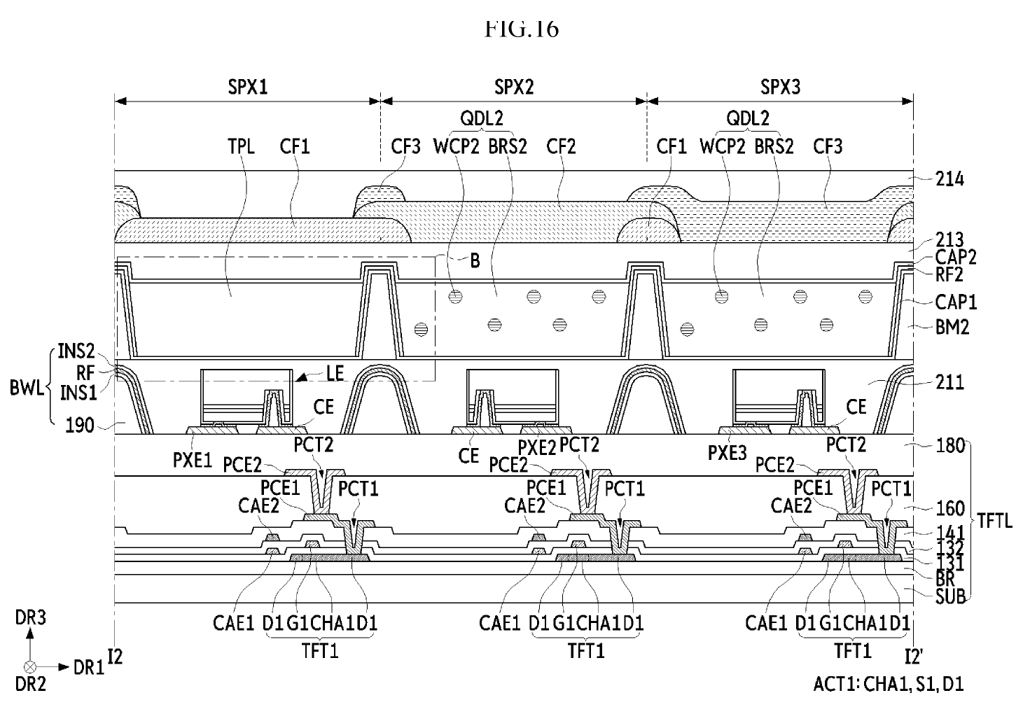

FIG. 16 is a cross-sectional diagram illustrating an example of a cross-section of a display panel taken along the line I2-I2’ of FIG. 15. FIG. 17 is a cross-sectional diagram illustrating an example of B area of FIG. 16 in detail.

The embodiments of FIGS. 16 and 17 differ from the embodiments of FIGS. 6 and 7 in that the light-emitting element LE is a flip type micro LED. In FIGS. 16 and 17, descriptions that overlap with the embodiments of FIGS. 6 and 7 will be omitted, and differences from the embodiments of FIGS. 6 and 7 will be mainly described.

Referring to FIGS. 16 and 17, a pixel electrode layer including pixel electrodes PXE1, PXE2, and PXE3 and common electrodes CE1, CE2, and CE3 may be arranged on a second planarization organic film 180.

The light-emitting element LE may be a flip type micro LED. The flip type micro LED refers to an LED in which contact electrodes CTE1 and CTE2 are formed on one surface (e.g., the bottom surface) of the light-emitting element LE.

In FIG. 17, the protective film INS is arranged on the side surfaces of the first semiconductor layer SEM1, the side surfaces of the active layer MQW, and the side surfaces of the second semiconductor layer SEM2 of the semiconductor stack STC, but not arranged on the side surfaces of the third semiconductor layer SEM3, but the present disclosure is not limited thereto. For example, the protective film INS may be arranged on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

The organic partition wall BWL may be formed on the second planarization organic film 180 with a first inclination angle θ1 and a first height h1.

The first inclination angle θ1 may be about 120 degrees or more. For example, the first inclination angle θ1 may be about 120 degrees to about 135 degrees. The first height h1 may be about 5 μm to about 6 μm.

The organic partition wall BWL may define a first opening area OP-A. The first opening area OP-A may expose the second planarization organic film 180 as a lower layer, the pixel electrodes PXE1, PXE2, and PXE3, and the common electrode CE. The area exposed by the first opening area OP-A may be larger than the area of the light-emitting element LE.

The organic partition wall BWL may include a first organic layer 190 defining the shape of the partition wall, a first protective film INS1 covering the first organic layer 190, a reflective film RF, and a second protective film INS2.

The reflective film RF is arranged outside the first protective film INS1. A second protective film INS2 is arranged on top of the reflective film RF. The reflective film RF is surrounded by the first protective film INS1 and the second protective film INS2.

The reflective film RF may be a closed loop shape that surrounds the side of the light-emitting element LE while being spaced apart from the light-emitting element LE on a plane. The upper end of the reflective film RF may be positioned higher than the active layer MQW of the light-emitting element LE. The lower end of the reflective film RF may be positioned lower than the light-emitting element LE. The reflective film RF may include a metal material having a high reflectivity, such as aluminum (Al).

The vertical distance from the uppermost end of the reflective film RF to the lowermost end is from about 80% to about 120% of the height of the light-emitting element LE.

A plurality of light-emitting elements LE may be arranged on the pixel electrodes PXE1, PXE2, and PXE3 and the common electrode CE.

A first contact electrode CTE1 may be arranged on the pixel electrodes PXE1, PXE2, and PXE3, and a second contact electrode CTE2 may be arranged on the common electrode CE.

A hole LEH may be formed to penetrate the conductive layer E1, the first semiconductor layer SEM1, and the active layer MQW of the light-emitting element LE to expose the second semiconductor layer SEM2. The hole LEH may have a circular planar shape, but the present disclosure is not limited thereto. For example, the hole LEH may have a polygonal planar shape, such as an oval or a square.

In addition, the protective film INS may be arranged on the sidewall of the conductive layer E1 exposed in the hole LEH, the sidewall of the first semiconductor layer SEM1, the sidewall of the active layer MQW, and the sidewall of the second semiconductor layer SEM2. The protective film INS may not cover the second semiconductor layer SEM2 in the hole LEH.

The first contact electrode CTE1 may be arranged on one surface of the conductive layer E1. Thus, the first contact electrode CTE1 may be electrically connected to the conductive layer E1.

The second contact electrode CTE2 may be arranged on one surface of the conductive layer E1 to be spaced apart from the first contact electrode CTE1. The second contact electrode CTE2 may be arranged on the protective film INS arranged in the hole LEH and the second semiconductor layer SEM2 exposed in the hole LEH without being covered by the protective film INS. Therefore, the second contact electrode CTE2 may be electrically connected to the second semiconductor layer SEM2 in the hole LEH.

FIG. 18 is a cross-sectional diagram illustrating another example of B area of FIG. 16 in detail.

The one or more embodiments corresponding to FIG. 18 differs from the one or more embodiments corresponding to FIG. 17 in that the organic partition wall BWL includes a first organic layer 191 and a second organic layer 192. In FIG. 18, descriptions that overlap with the one or more embodiments corresponding to FIG. 17 will be omitted, and differences from the one or more embodiments corresponding to FIG. 17 will be mainly described.

Referring to FIG. 18, the organic partition wall BWL may include a first organic layer 191 and a second organic layer 192 arranged on the first organic layer 191.

The first organic layer 191 and the second organic layer 192 have different inclinations.

The inclination angle θ11 of the first organic layer 191 may be greater than the second inclination angle θ12 of the second organic layer 192. The average of the inclination angle θ11 of the first organic layer 191 and the second inclination angle θ12 of the second organic layer 192 may be about 120 degrees or more, and for example about 120 to about 135 degrees. For example, as shown in FIG. 10, the inclination angle θ11 of the first organic layer 191 may be about 132 degrees, the second inclination angle θ12 of the second organic layer 192 may be about 113.5 degrees, and the average of the inclination angle θ11 of the first organic layer 191 and the second inclination angle θ12 of the second organic layer 192 may be about 122.8 degrees. The sum of the heights of the first organic layer 191 and the second organic layer 192 may be about 4.48 μm.

FIG. 19 is a cross-sectional diagram illustrating another example of B area of FIG. 16 in detail.

The one or more embodiments corresponding to FIG. 19 differs from the one or more embodiments corresponding to FIG. 15 in that the organic partition wall BWL includes a first organic layer 191-1, a second organic layer 192-1, and a third organic layer 193. In FIG. 17, overlapping descriptions with the one or more embodiments corresponding to FIG. 15 will be omitted, and differences from the one or more embodiments corresponding to FIG. 15 will be mainly described.

Referring to FIG. 19, the organic partition wall BWL may include a first organic layer 191-1 and a second organic layer 192-1 arranged on the first organic layer 191-1. Also, the organic partition wall BWL may further include a third organic layer 193 arranged on the second organic layer 192-1.

The first organic layer 191-1, the second organic layer 192-1, and the third organic layer 193 have different slopes. The slope of the organic layer arranged at the bottom may be greater. For example, the inclination angle θ21 of the first organic layer 191-1 may be greater than the inclination angle θ22 of the second organic layer 192-1, and the inclination angle θ22 of the second organic layer 192-1 may be greater than the inclination angle θ23 of the third organic layer 193.

The average of the inclination angles of the plurality of organic layers may be about 120 degrees or more, and for example about 120 to about 135 degrees. For example, the average of the inclination angle θ21 of the first organic layer 191-1, the inclination angle θ22 of the second organic layer 192-1, and the inclination angle θ23 of the third organic layer 193 may be about 120 to about 135 degrees.

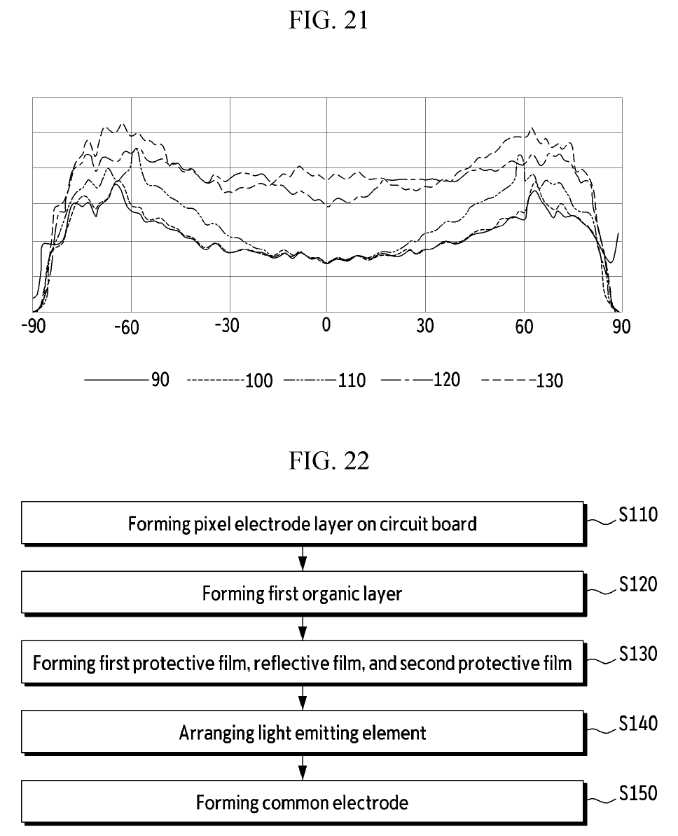

FIG. 20 is a graph illustrating LEE (light extraction efficiency) and luminance according to an angle of an organic partition wall. FIG. 21 is a graph illustrating an emission profile according to an angle of an organic partition wall.

The one or more embodiments corresponding to FIG. 20 illustrates LEE (a) and luminance (b) that appear by changing the inclination angle of the organic partition wall BWL in the display devices of FIGS. 6 and 7, and the one or more embodiments corresponding to FIG. 21 illustrates the front light emission profile that appears by changing the inclination angle of the organic partition wall BWL in the display devices of FIGS. 6 and 7. In FIG. 21, the unit of the front light emission profile is nit.

The inclination angle of the organic partition wall BWL is the same as the inclination angle of the first organic layer 190 and the inclination angle of the reflective film RF. For example, if the inclination angle of the organic partition wall BWL is about 120 degrees, the inclination angle of the first organic layer 190 of the corresponding organic partition wall BWL and the inclination angle of the reflective film RF may also be the same as about 120 degrees.

Referring to FIG. 20, if the inclination angle of the organic partition wall BWL is 90 degrees, LEE (a) and luminance (b) generally increase as the inclination angle of the organic partition wall BWL increases.

For example, if the inclination angle of the organic partition wall BWL is 100 degrees compared to the inclination angle of the reference organic partition wall BWL of about 90 degrees, LEE(a) increases slightly to about 104% and brightness(b) increases slightly to about 104%, and if the inclination angle of the organic partition wall BWL is about 100 degrees, LEE(a) increases slightly to about 129% and brightness(b) increases slightly to about 105%. In addition, if the inclination angle of the organic partition wall BWL is about 120 degrees compared to about 90 degrees, LEE(a) significantly increases to about 152% and luminance(b) significantly increases to about 222%, and if the inclination angle of the organic partition wall BWL is about 100 degrees, LEE(a) significantly increases to about 168% and luminance(b) significantly increases to about 279%.

In this way, the LEE(a) and the luminance(b) significantly increase based on about 120 degrees.

Referring to FIG. 21, if the inclination angle of the organic partition wall BWL is about 90 degrees based on LEE(a) and luminance(b), the frontal light emission profile from -60 to +60 significantly increases if the inclination angle of the organic partition wall BWL is about 120 degrees or more.

Therefore, in the display device, the average inclination angle of the organic partition wall BMW is greater than or equal to about 120 degrees to improve the LEE (a), luminance (b), and frontal luminous efficiency.

FIG. 22 is a flowchart illustrating a method of manufacturing a display device according to one or more embodiments.

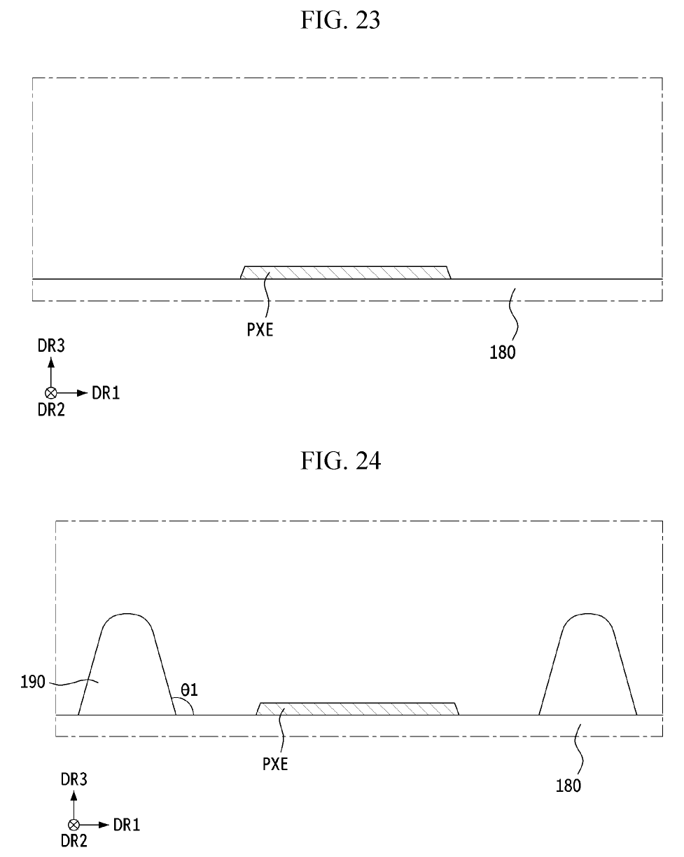

FIG. 23 to FIG. 28 illustrate a method of manufacturing a display device according to one or more embodiments.

Hereinafter, a method for manufacturing a display device according to one or more embodiments will be described in detail by connecting FIG. 22 with FIGS. 23 to 28. The method for manufacturing a display device described with reference to FIGS. 23 to 28 may be a display device including a light-emitting element and a display panel described with reference to FIGS. 5 to 7. FIGS. 23 to 28 are cross-sectional views of a display panel corresponding to FIG. 7. In some drawings, a plan view corresponding to the cross-sectional view is also illustrated for convenience of explanation.

First, a pixel electrode layer is formed on a circuit board (S110 in FIG. 22)

As shown in FIG. 23, the circuit board includes a second planarization organic film 180, and a pixel electrode PXE is formed on the second planarization organic film 180. For example, a conductive material layer is entirely deposited on the second planarization organic film 180, a mask pattern is formed on the conductive material layer, and a conductive material layer not covered by the mask pattern is etched. Thereafter, the mask pattern is removed by an ashing process to form a pixel electrode PXE. In one or more other embodiments, as shown in FIGS. 14 and 15, a pixel electrode and a common electrode may be formed as a pixel electrode layer on the second planarization organic film 180.

Second, a first organic layer 190 having a first opening area OP-A (e.g., see FIG. 7) is formed (S120 in FIG. 22)

Referring to FIG. 24, the first organic layer 190 having the first opening area OP-A may be formed by an inkjet process using an organic material but is not limited thereto.

The inclination angle θ1 of the first organic layer 190 may be about 120 degrees to about 135 degrees.

In FIG. 24, the first organic layer 190 is formed as a single layer, but is not limited thereto, and may be formed as a multilayer organic layer as shown in FIGS. 8 to 12. When formed with multiple organic layers, the lower organic layer (e.g., the first organic layer 191) may be formed, and the upper organic layer (e.g., the second organic layer 192) may be formed on the organic layer. When forming multiple organic layers, the average inclination angle of each organic layer may be 120 to about 135 degrees.

Third, an organic partition wall BMW is formed by arranging a first protective film INS1, a reflective film RF, and a second protective film INS2 on the first organic layer 190 (S130 in FIG. 22)

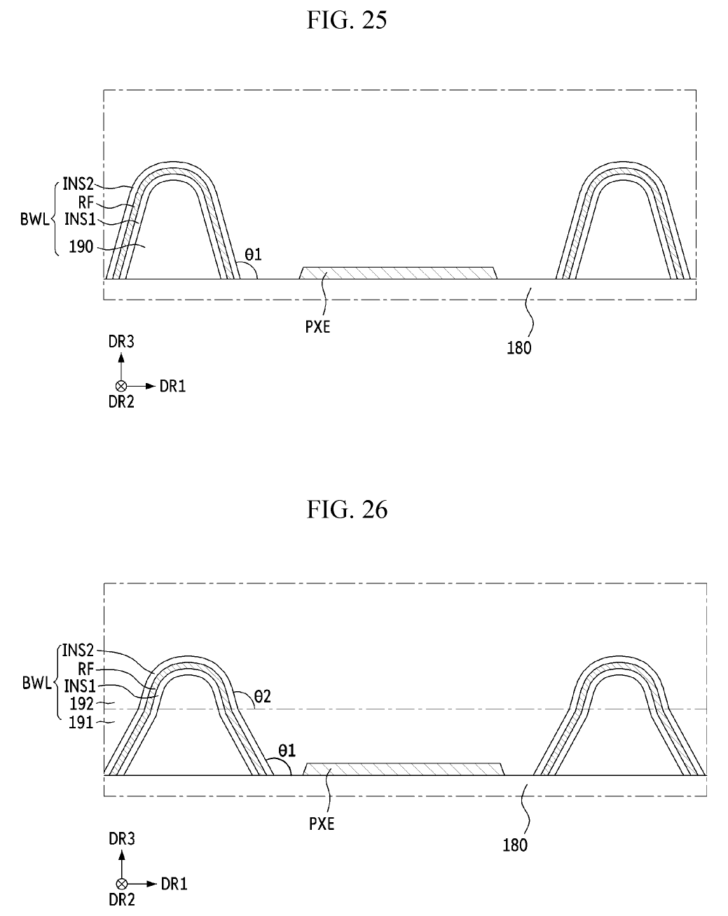

Referring to FIG. 25, a protective material layer is formed on the entire surface of the second planarization organic film 180 of the circuit board. Next, a reflective material layer is deposited on the entire surface of the second planarization organic film 180, and the reflective material layer is patterned to form a reflective film RF on the outside of the first protective layer INS1 overlapping the first organic layer 190. Then, a protective material layer is formed on the entire surface of the second planarization organic film 180 to completely cover the reflective film RF. Thereafter, a portion of the protective material layers within the first opening area OP-A are removed from the pixel electrode PXE and a portion of the second planarization organic film 180 surrounding the pixel electrode PXE. Thus, an organic partition wall BMW having a three-layer structure of a first protective film INS1, a reflective film RF, and a second protective film INS2 is formed on the first organic layer 190. The reflective film RF may be surrounded by the first protective film INS1 and the second protective film INS2.

Fourth, the light-emitting element LE is placed on the pixel electrode layer (S140 in FIG. 22)

The light-emitting elements LE may be grown on a semiconductor substrate. The semiconductor substrate may be a silicon wafer substrate or a sapphire substrate.

A plurality of semiconductor layers may be formed on the semiconductor substrate through an epitaxial growth process. As the epitaxial growth process, electron beam deposition, physical vapor deposition (PVD), chemical vapor deposition (CVD), plasma laser deposition (PLD), dual-type thermal evaporation, sputtering, metal organic chemical vapor deposition (MOCVD), and the like may be used. For example, a metal-organic chemical vapor deposition (MOCVD) method may be used, but the embodiments of the present disclosure are not limited thereto. The plurality of semiconductor layers may include a first semiconductor layer, an active layer, and a second semiconductor layer.

After forming the semiconductor layer, a conductive layer and a contact electrode may be formed on the semiconductor layer.

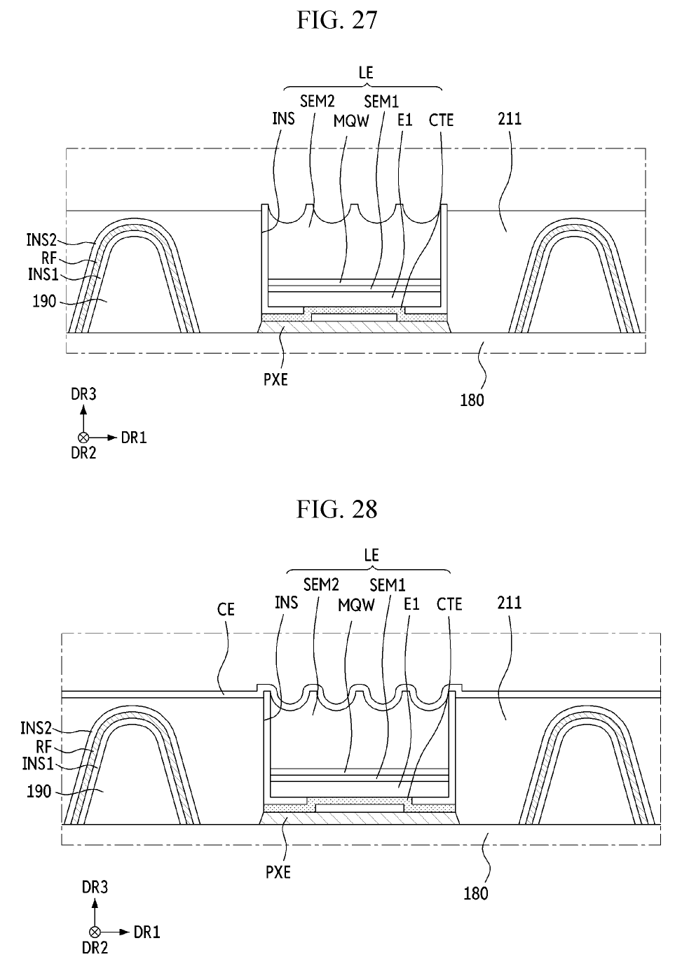

Referring to FIG. 27, the light-emitting elements (LEs) can be transferred directly from the semiconductor substrate onto the pixel electrode layer (e.g., the pixel electrode (PXE). Alternatively, the light-emitting elements (LEs) can be transferred onto the pixel electrodes (PXE) via an electrostatic method using an electrostatic head or a stamp method using an elastic polymer material, such as PDMS or silicon as a transfer substrate.

Referring to FIG. 27, the light-emitting elements LE may be transferred directly from the semiconductor substrate onto the pixel electrode layer (e.g., the pixel electrode PXE. Alternatively, the light-emitting elements LE may be transferred onto the pixel electrodes PXE through an electrostatic method using an electrostatic head or a stamp method using an elastic polymer material, such as PDMS or silicon as a transfer substrate.

Fifth, a common electrode CE is formed (S150 in FIG. 22)

Referring to FIG. 27, a second organic layer 211 is formed to fix the light-emitting elements LE and flatten the steps caused by the light-emitting elements LE. The second organic layer 211 may expose the upper portion of the light-emitting elements LE.

Referring to FIG. 28, a common electrode CE is formed on the light-emitting elements LE and the second organic layer 211. The common electrode CE may be in direct contact with the light-emitting elements LE.

Then, as shown in FIG. 7, at least one of a light-blocking layer, a wavelength conversion layer, a light transmission layer, or a color filter layer is additionally formed.

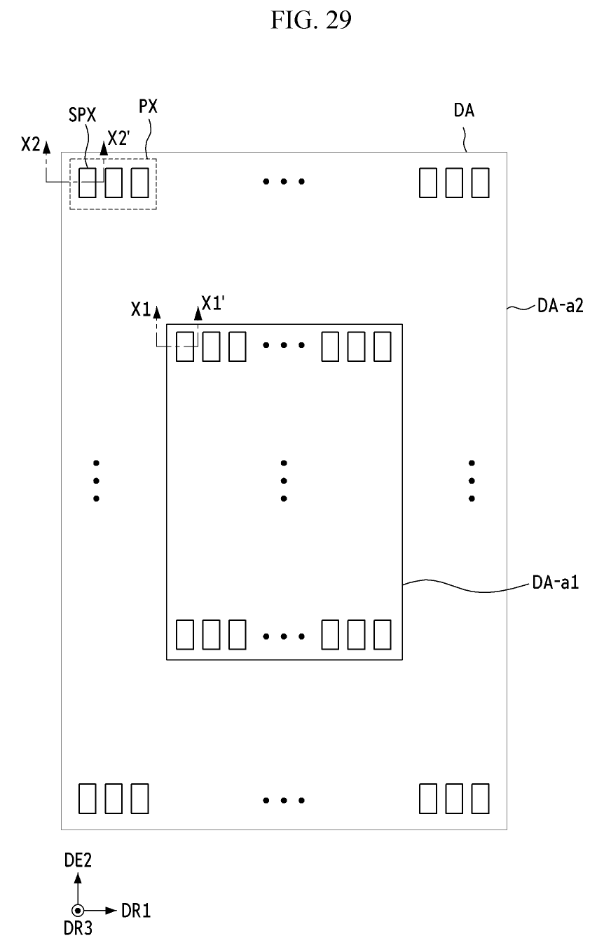

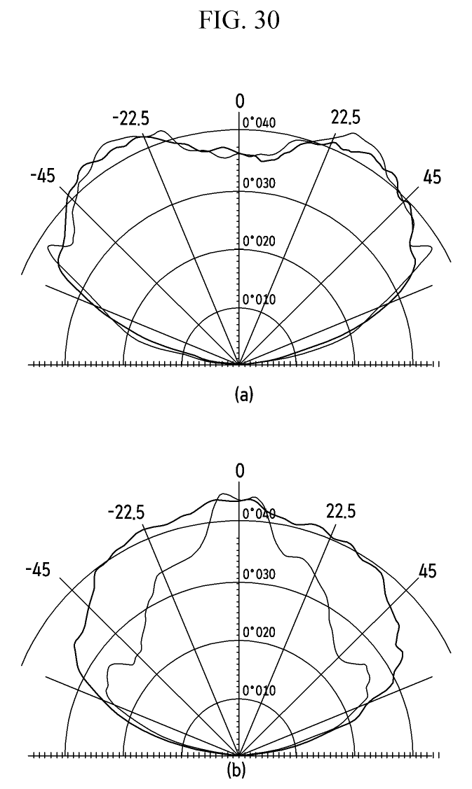

FIG. 29 is a plan view of a display panel according to one or more other embodiments.

As shown in FIG. 29, the display area DA of the display panel may be divided into a plurality of areas. For example, the display area DA may include a first area DA-a1 and a second area DA-a2.

The second area Da-a2 may be arranged adjacent to the first area DA-a1. The second area Da-a2 may be an outer area of the first area DA-a1. The second area Da-a2 may be arranged to surround the first area DA-a1. The second area Da-a2 may be an edge area of the first area DA-a1.

The first area DA-a1 may be an area having a higher luminance than the second area Da-a2. Each of the first area DA-a1 and the second area DA-a2 includes a plurality of pixels PX, and each of the plurality of pixels PX may include a plurality of sub-pixels SPX.

Each of the sub-pixel SPX of the first area DA-a1 may include one of the sub-pixels SPX described with reference to FIGS. 6 to 17. For example, the sub-pixel SPX of the first area DA-a1 may include a pixel electrode layer arranged on a thin film transistor layer (TFTL in FIG. 6), a light-emitting element LE arranged on the pixel electrode layer, and an organic partition wall BWL. Further, the sub-pixel SPX of the second area DA-a2 may include a pixel electrode layer arranged on a thin film transistor layer (TFTL in FIG. 6), a light-emitting element LE arranged on the pixel electrode layer, and an organic partition wall BWL surrounding the light-emitting element LE.

When the first area DA-a1 has higher luminance than the second area Da-a2, the average of the inclination angles of the reflective layer included in the organic partition wall BWL arranged in the first area DA-a1 may be greater than the average of the inclination angles of the reflective layer included in the organic partition wall BWL arranged in the second area DA-a2. The average of the inclination angles of the reflective layer included in the organic partition wall BWL arranged in the first area DA-a1 may be about 120 degrees or more, and, for example, may be in the range of about 120 degrees to about 135 degrees.

FIG. 30 is a graph illustrating the simulation results of light emission of a light-emitting element depending on the presence or absence of an organic partition wall.

FIG. 30 (a) illustrates the light emission simulation result when the display device does not include an organic partition wall, and FIG. 30 (b) illustrates the light emission simulation result when the display device includes an organic partition wall (one or more embodiments of FIG. 8).

Referring to FIG. 30 (a) and (b), if the display device includes an organic partition wall, the light emission efficiency at the front increases.

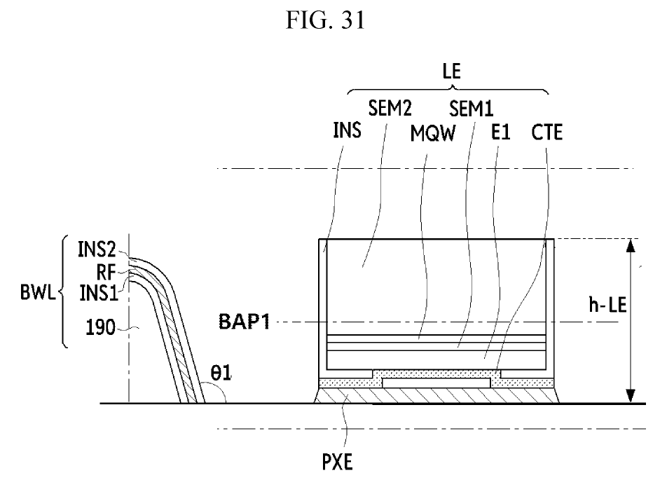

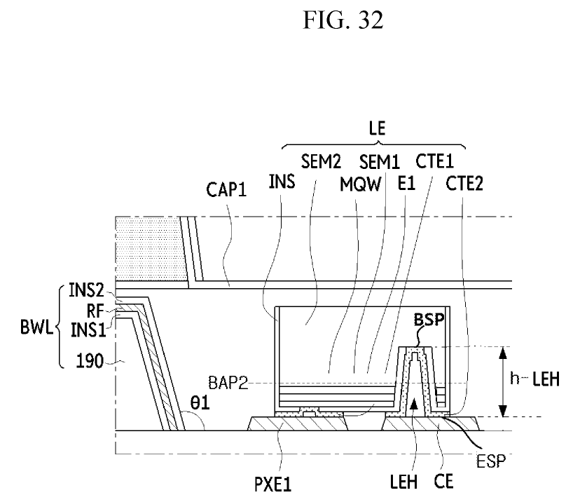

FIGS. 31 and 32 are drawings to illustrate a standard for measuring an angle of the outer surface of an organic partition wall according to one or more embodiments.

A reference plane may be used to measure the angle of the slope of the organic partition wall BWL. The reference plane may be defined by the light-emitting element LE. The reference plane may be determined as the boundary between the active layer and the second semiconductor layer, but if the boundary between the active layer and the second semiconductor layer, the reference plane may be found as follows.

Referring to FIG. 31, in the case of a vertical type light-emitting element LE according to one or more embodiments, the reference plane may be determined as a plane BAP1 passing through a point about 1/2 through the height of the light-emitting element LE. The point about 1/2 through the height of the light-emitting element LE may be confirmed by measuring the height of the highest point of the light-emitting element LE and then finding the point that is about 1/2 through the height h-LE to the highest point.

Referring to FIG. 32, in the case of a flip-type light-emitting element LE according to one or more embodiments, the reference plane may be set as a plane BAP2 passing through about 1/2 of the height h-LEH between the end surface ESP of the light-emitting element LE and the bottom surface BSP of the hole LEH. A measurement area is set to measure the angle of the outer surface of the organic partition wall BWL, first. The measurement area is set to include the outer surface of the organic partition wall BWL corresponding to the reference plane.

Next, the horizontal length of the measurement area and the height of the measurement area are measured. The inclination angle is calculated by utilizing the tangent value of the height of the measurement area with respect to the horizontal length of the measurement area.

Equipment capable of measuring thickness (step) and width may be used to measure the angle of the outer surface of the organic partition wall. Equipment capable of measuring thickness (step) and width include, for example, CD-SEM, AFM, WSI (white-light Scanning interferometer/Confocal… etc.).

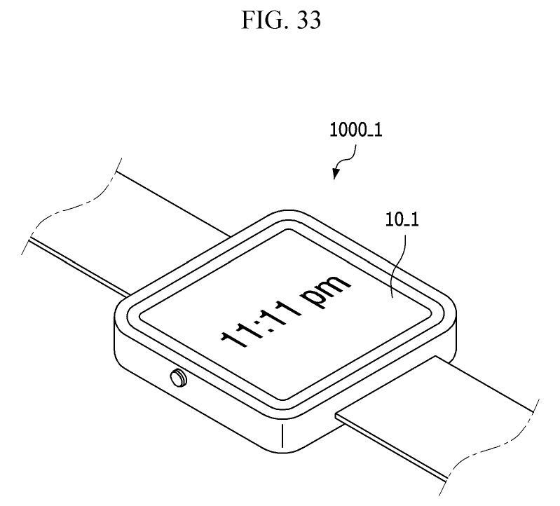

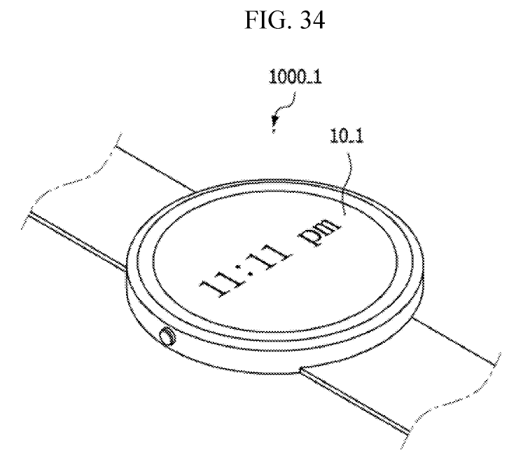

FIGS. 33 and 34 illustrate a smart watch including a display device according to one or more embodiments.

Referring to FIGS. 33 and 34, a display device 10_1 according to one or more embodiments may be applied to a smart watch 1000_1, which is one of smart devices.

The flat shape of the display device 10_1 may be a square or a circle but is not limited thereto and may be modified in various ways, such as an oval.

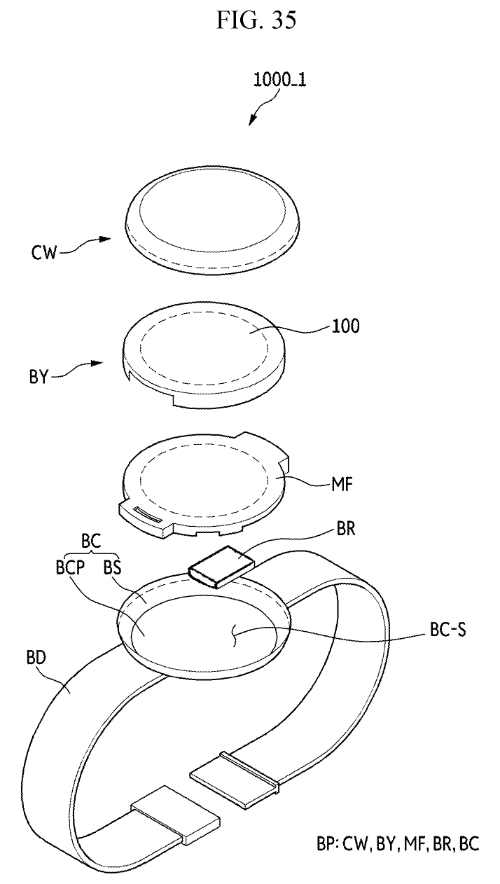

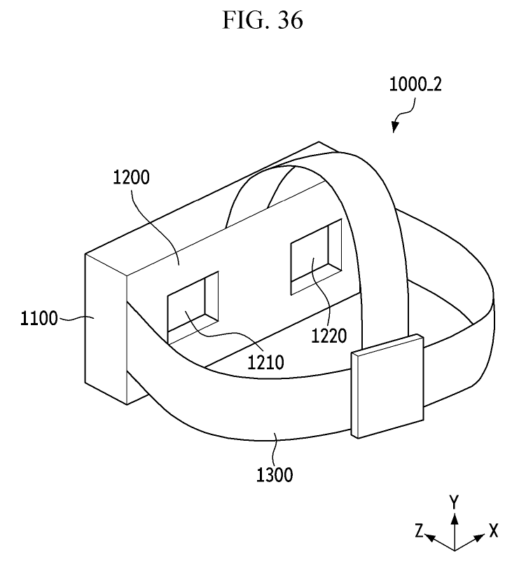

FIG. 35 is an exploded perspective view of a smart watch including a display device according to one or more embodiments.

Referring to FIG. 35, the smart watch 1000_1 may include a main body BP and a wearable portion BD.

The main body BP may include a display panel 100 on which an image is displayed, a cover window CW located on the display panel 100, a bottom cover BC located under the display panel 100, a middle frame MF located between the cover window CW and the bottom cover BC, and a battery BR located between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body BP may sequentially include a bottom cover BC, a battery BR, a middle frame MF, a display panel 100, and a cover window CW.

The cover window CW is arranged on the upper portion of the display panel 100 to protect the display panel 100 and to transmit light emitted from the display panel 100. As described above, the cover window CW may include a light-blocking portion to block a portion of the light emitted from the display panel 100. The cover window CW may be made of a transparent plastic material, a glass material, or a reinforced glass material.

The cover window CW may be arranged to overlap the display panel 100 and cover the front of the display panel 100. The cover window CW generally has a shape similar to that of the display panel 100 in terms of a plane, but its size may be larger than that of the display panel 100. For example, the cover window CW may protrude outward from the display panel 100. The plane shape of the cover window CW may be the same as that of the main body BP. For example, the planar shape of the cover window CW may be generally circular but is not limited thereto and may have various shapes, for example, a polygon, such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 100. The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a curvature (e.g., predetermined curvature), and the other portion may be flat. The degree (or angle) at which the peripheral portion BS is bent from the central cover portion BCP may be an obtuse angle, but is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, or a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body BP to the user's wrist, for example, and may be one of a strap, a chain, or a bracelet.

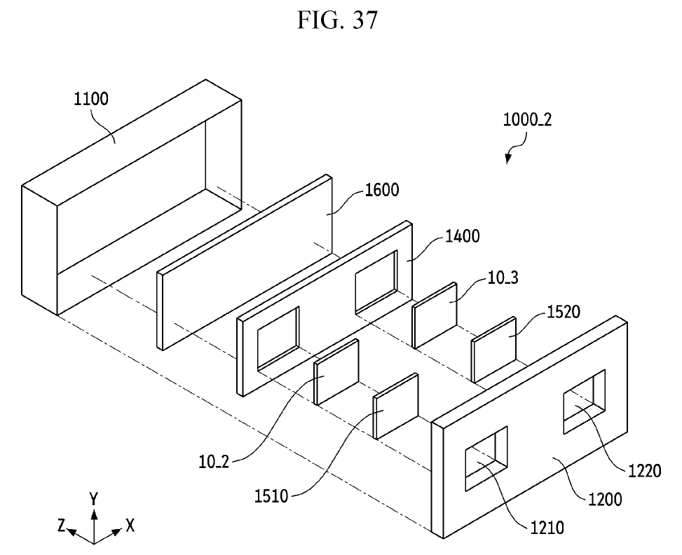

FIGS. 36 and 37 are example views of a virtual reality (VR) device including a display device according to one or more embodiments.

Referring to FIGS. 36 and 37, a head-mounted display device 1000_2 according to one or more embodiments includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to a user’s left eye, and the second display device 10_3 provides an image to the user’s right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600 and may be located between the second display device 10_3 and the control circuit board 1600. The middle frame 1400 supports and fixes the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image for a user’s left eye to the first display device 10_2 and may transmit the digital video data DATA corresponding to a right image for the user’s right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are located separately in FIGS. 33 and 34, the present disclosure is not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head-mounted band 1300 fixes the display device housing 1100 to a user’s head so that the first eyepiece 1210 and the second eyepiece 1220 of the housing cover 1200 are kept placed on the user’s left and right eyes, respectively. When the housing cover 1200 is implemented to be lightweight and small, the head-mounted display device 1000_2 may include an eyeglass frame as illustrated in FIG. 39 instead of the head-mounted band 1300.

In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi‑Fi® module, or a Bluetooth® module (Wi‑Fi® being a registered trademark of the non-profit Wi-Fi Alliance, and Bluetooth® being a registered trademark of Bluetooth Sig, Inc., Kirkland, WA).

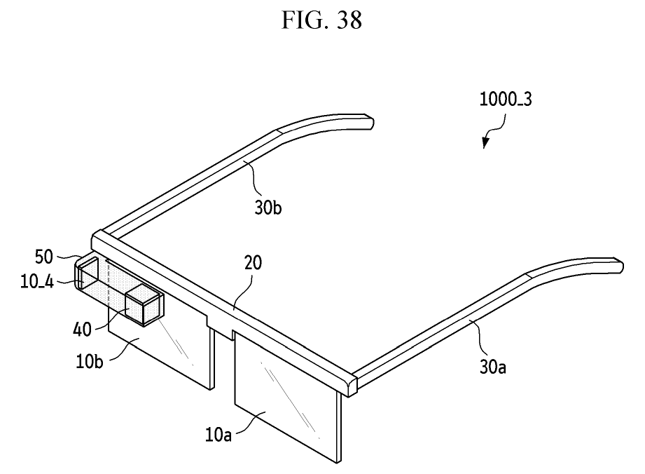

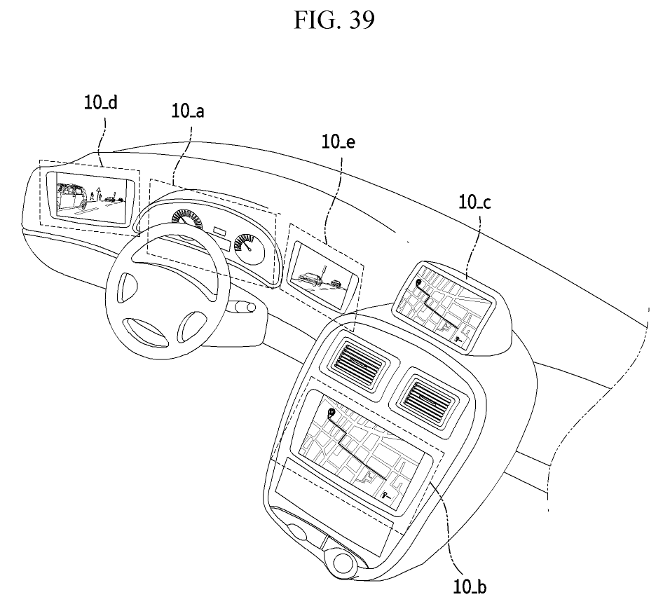

FIG. 38 is a view of a VR device including a display device according to one or more embodiments. FIG. 38 illustrates a VR device 1000_3 to which a display device 10_4 according to one or more embodiments has been applied.

Referring to FIG. 38, the VR device 1000_3 according to one or more embodiments may be a device in the form of glasses. The VR device 1000_3 may include the display device 10_4, a left lens 10a, a right lens 10b, a support frame 20, eyeglass frame legs 30a and 30b, a reflective member 40, and a display device housing 50.

In FIG. 38, a case where the VR device 1000_3 is a glasses-type display device including the eyeglass frame legs 30a and 30b is illustrated as an example. That is, the VR device 1000_3 is not limited to the one illustrated in FIG. 31 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is located at a right end of the support frame 20 in FIG. 38, the present disclosure is not limited thereto. For example, the display device housing 50 may also be located at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

FIG. 39 is a view illustrating a vehicle instrument cluster and center fascia including display devices according to one or more embodiments. FIG. 39 illustrates a vehicle to which display devices 10_a through 10_e according to one or more embodiments have been applied.

Referring to FIG. 39, the display devices 10_a through 10_c may be applied to an instrument cluster of the vehicle, a center fascia of the vehicle, or a center information display (CID) located on a dashboard of the vehicle. In addition, the display devices 10_d and 10_e may be applied to room mirror displays that replace side mirrors of the vehicle.

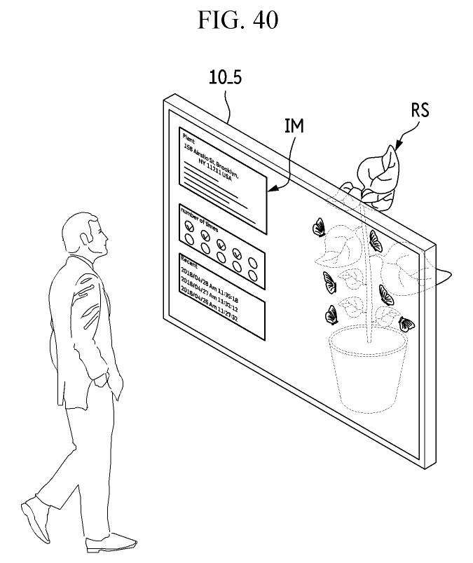

FIG. 40 is a view of a transparent display device including a display device according to one or more embodiments.

Referring to FIG. 40, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

It should be understood, however, that the aspects of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a thin film transistor layer above the substrate;
a planarization layer above the thin film transistor layer;
a pixel electrode layer above the planarization layer;
light-emitting elements comprising a first light-emitting element and a second light-emitting element arranged along a first direction above the pixel electrode layer;
an organic partition wall portion between the first light-emitting element and the second light-emitting element above the planarization layer, and comprising a first inclined portion toward the first light-emitting element and a second inclined portion toward the second light-emitting element, and
wherein the first light-emitting element comprises a first semiconductor layer, a first active layer configured to emit light of a first wavelength, and a second semiconductor layer,
wherein the second light-emitting element comprises a first semiconductor layer, a second active layer configured to emit light of a second wavelength that is different from the first wavelength, and a second semiconductor layer,
wherein the organic partition wall portion has:
a first angle between a first virtual surface, which extends parallel to a boundary between the second semiconductor layer and the first active layer of the first light-emitting element, and an outer surface of the first inclined portion; and
a second angle between a second virtual surface, which extends parallel to a boundary between the second semiconductor layer and the second active layer of the second light-emitting element, and an outer surface of the second inclined portion,
wherein the first angle is about 120 degrees or more, and the second angle is about 5 degrees or more larger than the first angle and about 135 degrees or less.

2. The display device of claim 1, wherein the organic partition wall portion comprises a 1-2 inclined portion above the first inclined portion,
wherein the second semiconductor layer of the first light-emitting element comprises a lower surface facing the first active layer and an upper surface facing the lower surface,
wherein the organic partition wall portion has a 1-2 angle between a 1-2 virtual surface, which extends parallel to the upper surface, and the outer surface of the 1-2 inclined portion, and
wherein the 1-2 angle is smaller than the first angle, and an average of the 1-2 angle and the first angle is about 120 degrees or more.

3. The display device of claim 2, wherein the average of the 1-2 angle and the first angle is about 120 degrees to about 135 degrees.

4. The display device of claim 2, wherein the organic partition wall portion comprises:
an organic layer comprising the first inclined portion and the second inclined portion; and
a reflective film above the organic layer, comprising a first reflective film on the outer surface of the first inclined portion, and a second reflective film on the outer surface of the second inclined portion, and having a third angle between the outer surface of the first reflective film and the first virtual surface; and
a fourth angle between the outer surface of the second reflective film and the second virtual surface,
wherein the third angle is about 120 degrees or more, and the fourth angle is about 5 degrees or more larger than the third angle and about 135 degrees or less.

5. The display device of claim 4, further comprising a first protective film between the organic layer and the reflective film, and a second protective film outside the reflective film.

6. The display device of claim 4, wherein an inflection point of the first reflective film and the second reflective film are higher than an upper portion of the first active layer,
wherein the organic partition wall portion comprises a 2-2 inclined portion and has a 2-2 angle between a 2-2 virtual surface, which extends parallel to the upper surface, and an outer surface of the 2-2 inclined portion, and
wherein the 2-2 angle is smaller than the second angle, and an average of the 2-2 angle and the 2-2 angle is about 120 degrees or more.

7. The display device of claim 4, wherein a lower end portion of the reflective film is lower than a lower end portion of the light-emitting elements, and
wherein a shortest distance between the reflective film and a corresponding one of the light-emitting elements is less than a width of the corresponding one of the light-emitting elements.

8. The display device of claim 1, wherein the organic partition wall portion surrounds a corresponding one of the light-emitting elements in plan view.

9. The display device of claim 4, wherein an upper end of the reflective film is at a height of about 80% or more and about 120% or less of a height of the light-emitting elements.

10. The display device of claim 1, wherein the light-emitting elements further comprise a protective film on a side surface of the first semiconductor layer, a corresponding one of the first activation layer or the second active layer, and the second semiconductor layer, and does not have a reflective film on the protective film.

11. The display device of claim 10, further comprising a common electrode above an upper portion of the light-emitting elements,
wherein the pixel electrode layer comprises pixel electrodes, and
wherein the light-emitting elements are respectively above corresponding ones of the pixel electrodes.

12. The display device of claim 11, wherein the pixel electrode layer comprises pixel electrodes and the common electrode spaced apart from each other,
wherein the light-emitting elements are respectively above a corresponding one of the pixel electrodes and the common electrode.

13. The display device of claim 12, wherein the light-emitting elements comprise a first contact electrode respectively above the corresponding one of the pixel electrodes, and a second contact electrode above the common electrode.

14. A method for manufacturing a display device, the method comprising:
locating pixel electrodes above a planarization layer of a circuit board;
locating an organic partition wall portion between a first pixel electrode and a second pixel electrode in plan view and above the circuit board, and having a first incline portion and a second inclined portion;
locating a reflective film above the organic partition wall portion;
arranging a first light-emitting element above the first pixel electrode and comprising a first semiconductor layer, a first active layer configured to emit light of a first wavelength, and a second semiconductor layer; and
arranging a second light-emitting element above the second pixel electrode and comprising a first semiconductor layer, a second active layer configured to emit light of a second wavelength that is different from the first wavelength, and a second semiconductor layer,
wherein the organic partition wall portion has:
a first angle between a first virtual surface, which extends parallel to a boundary between the second semiconductor layer and the first active layer of the first light-emitting element, and an outer surface of the first inclined portion; and
a second angle between a second virtual surface, which extends parallel to a boundary between the second semiconductor layer and the second active layer of the second light-emitting element, and an outer surface of the second inclined portion, and
wherein the first angle is about 120 degrees or more, and the second angle is about 5 degrees or more larger than the first angle and about 135 degrees or less.

15. The method for manufacturing the display device of claim 14, wherein the locating the organic partition wall portion comprises:
locating a first organic layer above the circuit board; and
locating a second organic layer comprising a 1-2 inclined portion above the first organic layer, and having a 1-2 angle between a 1-2 virtual surface, which extends parallel to an upper surface of the second semiconductor layer, and an outer surface of the 1-2 inclined portion, and
wherein the 1-2 angle is smaller than the first angle, and an average of the first angle and the 1-2 angle is about 120 degrees or more.

16. The method for manufacturing the display device of claim 15, wherein the locating the reflective film comprises:
locating a first protective material layer covering the first organic layer and the second organic layer above an entire surface of the circuit board;
locating the reflective film above the first protective material layer overlapping the first organic layer and the second organic layer;
locating a second protective material layer above the entire surface of the circuit board to cover the reflective film; and
patterning a portion of the first protective material layer and the second protective material layer to have a first protective film and a second protective film exposing a corresponding one of the first pixel electrode or the second pixel electrode.

17. An electronic device comprising:
a display panel;
a window above the display panel; and
a bottom cover below the display panel,
wherein the display panel comprises,
a substrate;
a thin film transistor layer above the substrate;
a planarization layer above the thin film transistor layer;
a pixel electrode layer above the planarization layer;
light-emitting elements comprising a first light-emitting element and a second light-emitting element arranged along a first direction above the pixel electrode layer;
an organic partition wall portion between the first light-emitting element and the second light-emitting element in plan view and above the planarization layer, and comprising a first inclined portion toward the first light-emitting element and a second inclined portion toward the second light-emitting element,
wherein the first light-emitting element comprises a first semiconductor layer, a first active layer configured to emit light of a first wavelength, and a second semiconductor layer,
wherein the second light-emitting element comprises a first semiconductor layer, a second active layer configured to emit light of a second wavelength that is different from the first wavelength, and a second semiconductor layer,
wherein the organic partition wall portion has:
a first angle between a first virtual surface, which extends parallel to a boundary between the second semiconductor layer and the first active layer of the first light-emitting element, and an outer surface of the first inclined portion; and
a second angle between a second virtual surface, which extends parallel to a boundary between the second semiconductor layer and the second active layer of the second light-emitting element, and an outer surface of the second inclined portion, and
wherein the first angle is about 120 degrees or more, and the second angle is about 5 degrees or more larger than the first angle and about 135 degrees or less.

18. The electronic device of claim 17, further comprising a battery in a space at least partially defined by the bottom cover and configured to supply power to the display panel; and
a middle frame between the window and the bottom cover.

19. The electronic device of claim 17, wherein the display panel comprises a display area and a non-display area,
wherein the display area comprises a first display area and a second display area,
wherein the first display area comprises a 1-1 light-emitting element and a first organic partition wall portion surrounding the 1-1 light-emitting element in plan view,
wherein the second display area comprises a 2-1 light-emitting element and a second organic partition wall portion surrounding the 2-1 light-emitting element in plan view, and
wherein a 11-1 angle between a 11-1 virtual surface, which is parallel to a boundary between a second semiconductor layer and a first active layer of the 1-1 light-emitting element, and the outer surface of the first inclined portion is smaller than a 11-2 angle between a 11-2 virtual surface, which is parallel to a boundary between a second semiconductor layer and a second active layer of the 2-1 light-emitting element, and the outer surface of the second inclined portion.

20. The electronic device of claim 19, wherein the second display area is at an outer side of the first display area on a plane.
